(19) United States
(12) Patent Application Publication
(10) Pub. No.: US 2025/0270372 A1
(43) Pub. Date: Aug. 28, 2025

(54) BISMALEIMIDE COMPOUND, RESIN COMPOSITION INCLUDING SAME, CURED OBJECT THEREFROM, SEMICONDUCTOR ELEMENT AND DRY FILM RESIST

(71) Applicant: NIPPON KAYAKU KABUSHIKI KAISHA, Tokyo (JP)

(72) Inventors: Kazuyoshi YAMAMOTO, Tokyo (JP); Mai TSUBAMOTO, Tokyo (JP); Mao TAKEDA, Tokyo (JP); Ryutaro TANAKA, Tokyo (JP)

(73) Assignee: NIPPON KAYAKU KABUSHIKI KAISHA, Tokyo (JP)

(21) Appl. No.: 18/859,705

(22) PCT Filed: Aug. 31, 2022
(86) PCT No.: PCT/JP2022/032794

§ 371 Date: Oct. 24, 2024

(30) Foreign Application Priority Data
Apr. 25, 2022 (JP) 2022-071709

(51) Int. Cl. C08G 73/12; G03F 7/004; G03F 7/038

(52) U.S. Cl. CPC C08G 73/126; G03F 7/0045; G03F 7/0387

(57) ABSTRACT

This bismaleimide compound (I) is obtained by reacting an aromatic diamine (A) represented by formula (1), a tetrabasic acid dianhydride (C), and maleic acid anhydride and having a cyclic imide bond. The R₁ moieties each independently represent a hydrogen atom, a C1-C6 linear or branched alkyl group, a halogen atom, a hydroxy group, or a C1-C6 linear or branched alkoxy group, and each 1 independently represents an integer of 1-4.

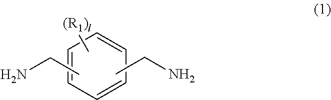

### TECHNICAL FIELD

The present invention relates to a bismaleimide compound, a resin composition using the same, a cured product thereof, and a semiconductor device. The resin composition of the present invention can be used as a protective film for semiconductor devices, an interlayer insulating film, an insulating film for a rewiring layer, etc.

### BACKGROUND ART

In recent years, electronic devices have become smaller and more powerful, and there is a demand for finer and denser wiring in the surface protection films and interlayer insulating films of semiconductor elements, as well as the insulating films of redistribution lavers. Furthermore, materials for high frequency bands will be required in the next generation, and the reduction of transmission loss will be essential as a noise countermeasure, so there is a demand for the development of insulating materials with excellent dielectric properties.

Conventionally, polyimide resins and polybenzoxazole resins, which have excellent heat resistance and mechanical properties, have been widely used for surface protective films and interlayer insulating films of semiconductor elements (for example, Patent Literature 1). When polyimide resins and polybenzoxazole resins are used as surface protective films and interlayer insulating films, a method of forming through holes and the like by etching using a positive photoresist containing the same resin as these resins is known. However, this method has a problem in that it requires complicated processes such as applying and peeling off the photoresist. Therefore, heat-resistant materials to which photosensitivity has been imparted have been studied for the purpose of streamlining the work process (Patent Literature 2). It has been found that materials such as polyimide resins and polybenzoxazole resins do not have satisfactory dielectric properties for high-frequency band applications represented by the keyword 5G. In contrast, Patent Literature 3 reports that an epoxy resin composition containing an epoxy resin, an active ester compound, and a triazine-containing cresol novolak resin is effective in reducing the dielectric tangent, but even this material needs to be made even lower for high-frequency applications.

On the other hand, Patent Literature 4 reports that a resin film made of a resin composition containing a bismaleimide resin having a long-chain alkyl group as a non-epoxy material and a curing agent has excellent low dielectric properties.

Furthermore, Patent Literatures 5 and 6 disclose polyimides made from dimer diamines and alicyclic diamines derived from aromatic tetracarboxylic acids and dimer acids, which are dimers of unsaturated fatty acids such as oleic acid.

### CITATION LIST

### Patent Literature

Patent Literature 1: JPA1999-199557
Patent Literature 2: JPA1999-24271
Patent Literature 3: JPA2011-132507
Patent Literature 4: WO2016/114287
Patent Literature 5: JPA2017-119361
Patent Literature 6: JPA2019-104843

### SUMMARY OF THE INVENTION

### Problem to be Solved by the Invention

The film described in Patent Literature 4 is essentially a combination of a bismaleimide resin having a long-chain alkyl group and a hard low-molecular aromatic maleimide, and is poorly compatible, prone to uneven properties and curing, and very difficult to achieve a high glass transition temperature (Tg) of 200° C. or more required for semiconductor element applications. In addition, recent research has revealed that the bismaleimide resin having the long-chain alkyl group described above has a trade-off relationship in resin design, in that increasing the glass transition temperature leads to poorer dielectric properties, and improving the dielectric properties leads to a lower glass transition temperature. It has also been found that increasing the glass transition temperature causes aggregation and separation between the resins, even between bismaleimide resins having the same long-chain alkyl group, and also leads to poor compatibility between the resins. Furthermore, the polyimides described in Patent Literature 5 and Patent Literature 6 are difficult to use for curing alone, and are poorly compatible with other resins. In addition, since polyimide undergoes ring-closing dehydration during curing, voids may occur and flattening may not be possible depending on the conditions of use, for example, when stacking a rewiring layer.

Therefore, an object of the present invention is to provide a bismaleimide compound which has good compatibility with other resins and a high glass transition temperature.

### Solution to the Problem

The present inventors have conducted extensive research to solve the above problems and have found that the following bismaleimide compound (1) can achieve the above object, thereby completing the present invention.

That is, the present invention includes the following aspects:

<1> A bismaleimide compound (I) having a cyclic imide bond, obtained by reacting an aromatic diamine (A) represented by the following formula (1), a tetrabasic acid dianhydride (C), and maleic anhydride.

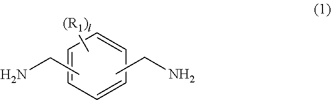

In formula (1), R₁ each independently represents a hydrogen atom, a linear or branched alkyl group having 1 to 6 carbon atoms, a halogen atom, a hydroxy group, or a linear or branched alkoxy group having 1 to 6 carbon atoms, 1 independently represents an integer from 1 to 4.

<2> The bismaleimide compound (I) according to <1>, which is obtained by reacting the diamine (A), the tetrabasic acid dianhydride (C), the maleic anhydride, and further a divalent organic diamine (B) having 6 to 200 carbon atoms other than the aromatic diamine (A).
<3> The bismaleimide compound (1) according to <1> or <2>, which is represented by the following general formula (2).

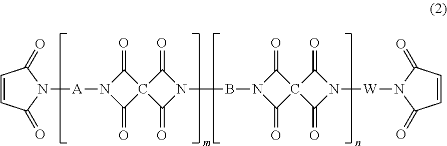

In formula (2),
C independently represents a tetravalent organic group containing a cyclic structure.
B independently represents a divalent hydrocarbon group having 6 to 200 carbon atoms.
W is A or B.
m is 1 to 100, and n is 0 to 100. The order of the repeating units bracketed by m and n is not limited, and the bonding pattern may be alternating, block, or random.
A independently represents a divalent linking group represented by the following formula (3).

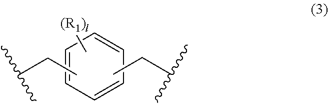

In formula (3), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer from 1 to 4.

<4> The bismaleimide compound (I) according to any one of <1> to <3>, wherein the tetrabasic acid dianhydride (C) contains a compound selected from the group consisting of the following formulae (4) to (12).

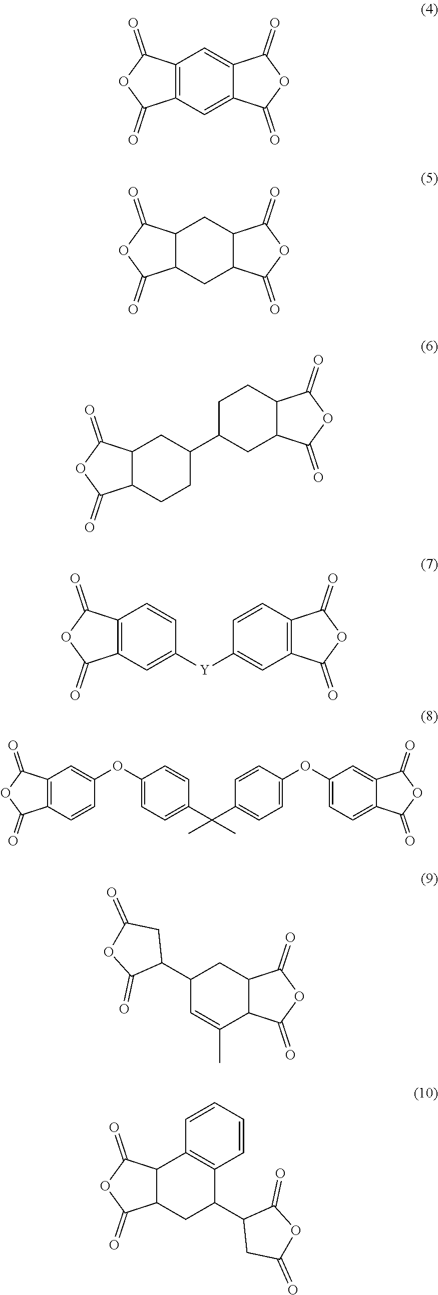

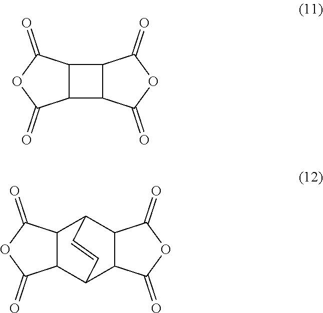

In formula (7), Y represents C(CF₃)₂, SO₂, CO, an oxygen atom, a direct bond, or a divalent linking group represented by the following formula (13).

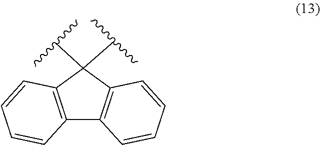 [SMILES: *C1(*)c2ccccc2-c2ccccc21]

<5> The bismaleimide compound (I) according to any one of <1> to <4>, which is a maleimide compound of an amine compound represented by the following formula (14):

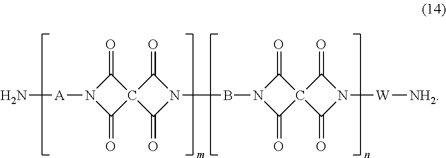

In formula (14). C independently represents a tetravalent organic group containing a cyclic structure. B independently represents a divalent hydrocarbon group having 6 to 200 carbon atoms. W is A or B. m is 1 to 100, and n is 0 to 100. The order of the repeating units bracketed by m and n is not limited, and the bonding pattern may be alternating, block, or random. A independently represents a divalent linking group represented by the following formula (3):

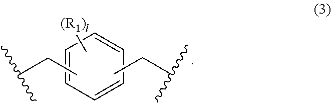

In formula (3), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer from 1 to 4.

<6> The bismaleimide compound (I) according to any one of <1> to <5>, wherein the tetrabasic acid dianhydride (C) is a compound represented by the following formula (15):

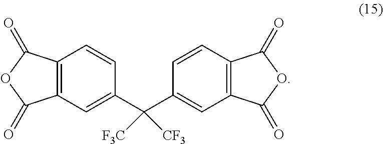 [SMILES: O=C1OC(=O)c2cc(C(c3ccc4c(c3)C(=O)OC4=O)(C(F)(F)F)C(F)(F)F)ccc21]

<7> The bismaleimide compound (I) according to any one of <1> to <5>, wherein the tetrabasic acid dianhydride (C) is a compound represented by the following formula (8):

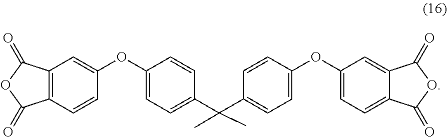 [SMILES: CC(C)(c1ccc(Oc2ccc3c(c2)C(=O)OC3=O)cc1)c1ccc(Oc2ccc3c(c2)C(=O)OC3=O)cc1]

<8> The bismaleimide compound (I) according to any one of <1> to <5>, wherein the tetrabasic acid dianhydride (C) is a compound represented by the following formula (5).

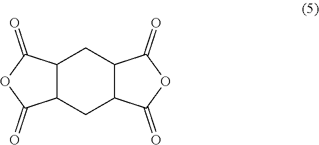 [SMILES: O=C1OC(=O)C2CC3C(=O)OC(=O)C3CC12]

<9> The bismaleimide compound (I) according to any one of <1> to <5>, wherein the tetrabasic acid dianhydride (C) is a compound represented by the following formula (9).

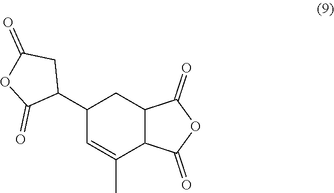 [SMILES: CC1=CC(C2CC(=O)OC2=O)CC2C(=O)OC(=O)C12]

<10> The bismaleimide compound (I) according to any one of <1> to <5>, wherein the tetrabasic acid dianhydride (C) is a compound represented by the following formula (10).

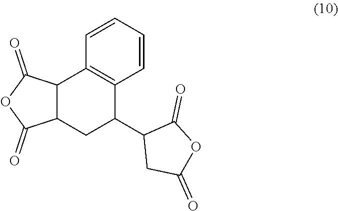 [SMILES: O=C1CC(C2CC3C(=O)OC(=O)C3c3ccccc32)C(=O)O1]

<11> A composition comprising the bismaleimide compound (I) according to any one of <1> to <10> and a compound capable of reacting with a maleimide group.
<12> The resin composition according to claim 11, further comprising at least one selected from the group consisting of maleimide compounds other than the maleimide compound (I) according to any one of <1> to <10>, cyanate ester compounds, phenolic resins, epoxy resins, oxetane resins, benzoxazine compounds, carbodiimide compounds, and compounds having an ethylenically unsaturated group.
<13> A composition comprising the bismaleimide compound (I) according to any one of <1> to <10> and a photopolymerization initiator or a curing catalyst.
<14> The resin composition according to any one of <11> to <13>, further comprising a filler.
<15> A cured object of the resin composition comprising the bismaleimide compound (I) according to any one of <1> to <10>.
<16> A semiconductor element comprising a surface protective film, an interlayer insulating film, or an insulating film of a redistribution layer, which contains the bismaleimide compound (I) according to any one of <1> to <10>.
<17> A dry film resist comprising a composition containing the bismaleimide compound (I) according to any one of <1> to <10> and a photopolymerization initiator.

### Effect of the Invention

The bismaleimide compound (I) of the present invention, particularly a bismaleimide compound having an aromatic ring skeleton, has excellent compatibility with resins having different structures, and is therefore easily used in combination with other resins, and it is easy to complement each other's performance to bring out better performance. Furthermore, the bismaleimide compound of the present invention, particularly a bismaleimide compound having an aromatic ring skeleton, can provide a bismaleimide resin composition that gives a cured product having a high glass transition point (Tg).

### DETAILED DESCRIPTION OF THE EMBODIMENTS

The present invention will be described in detail below.

### <Bismaleimide Compound (I)>

The bismaleimide compound (I) according to the present invention is a compound having two maleimide groups, and has a cyclic imide bond with an aromatic diamine (A) represented by the following formula (1). Such a bismaleimide compound (I) can be obtained by reacting the aromatic diamine (A) represented by the following formula (1) with a tetrabasic acid dianhydride (C) and maleic anhydride.

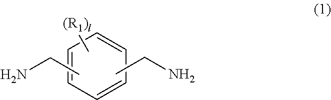

In formula (1), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4.

In addition to the aromatic diamine (A), the tetrabasic acid dianhydride (C), and the maleic anhydride, a divalent aliphatic diamine (B) having 6 to 200 carbon atoms other than the aromatic diamine (A) is reacted to form an imide bond, which can be introduced into the bismaleimide compound.

The bismaleimide compound (I) is preferably a bismaleimide compound represented by the following general formula (2).

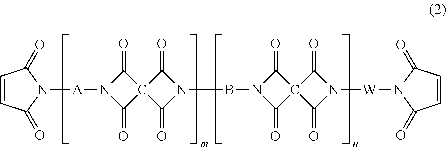

The bismaleimide compound is preferably a maleimide compound of an amine compound represented by the following formula (14).

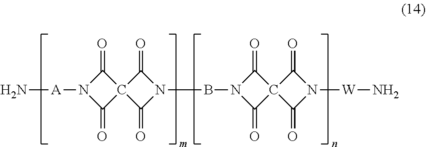

In formula (2) and formula (14), C independently represents a tetravalent organic group containing a cyclic structure. B independently represents a divalent hydrocarbon group having 6 to 200 carbon atoms. W is A or B, m is 1 to 100, and n is 0 to 100. The order of the repeating units bracketed by m and n is not limited, and the bonding mode may be alternating, block, or random. A independently represents a divalent linking group represented by the following formula (3).

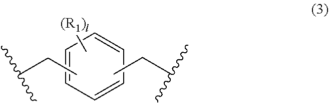

In formula (3), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4.

The linear or branched alkyl group having 1 to 6 carbon atoms is not particularly limited, and examples thereof include methyl, ethyl, n-propyl, i-propyl, butyl, isobutyl, sec-butyl, and tert-butyl groups. Among these, alkyl groups having 1 to 4 carbon atoms are preferred, and methyl, ethyl, n-propyl, and i-propyl groups are more preferred, because they exhibit excellent adhesion to chips and substrates, as well as good solubility in solvents, low melting point, low water absorption, and good compatibility with other resins.

Examples of halogen atoms include fluorine, chlorine, bromine, and iodine atoms.

Examples of linear or branched alkoxy groups having 1 to 6 carbon atoms are not particularly limited, and examples thereof include methoxy, ethoxy, n-propoxy, iso-propoxy, n-butoxy, 2-methylpropoxy, 1-methylpropoxy, and tert-butoxy groups. Among these, alkoxy groups having 1 to 4 carbon atoms are preferred, and methoxy, ethoxy, n-propoxy, and iso-propoxy groups are more preferred, because they exhibit good solubility in solvents, low melting point, low water absorption, and good compatibility with other resins in addition to excellent adhesion to chips and substrates, etc.

As R₁, hydrogen atoms, methyl groups, ethyl groups, hydroxy groups, methoxy groups, and ethoxy groups are preferred; hydrogen atoms, methyl groups, and hydroxy groups are more preferred; and hydrogen atoms are even more preferred, because they exhibit good solubility in solvents, low melting point, low water absorption, and good compatibility with other resins in addition to excellent adhesion to chips and substrates, etc.

In the formulae (1) or (3), each 1 independently represents an integer of 1 to 4. Since it is preferable that all R₁ are hydrogen atoms, 1 is preferably 4 since all R₁ are preferably hydrogen atoms which exhibit good solubility in solvents, a low melting point, low water absorbency, and good compatibility with other resins in addition to excellent adhesion to chips and substrates, etc.

Specific examples of the aromatic diamine (A) represented by the formula (1) include aromatic diamines such as meta-xylenediamine (formula (17) below), para-xylenediamine (formula (18) below), and ortho-xylenediamine (formula (19) below). As a commercially available product, meta-xylenediamine (MXDA: manufactured by Mitsubishi Gas Chemical Company, Inc.) is easily available. As the aromatic diamine (A) represented by the formula (1), meta-xylenediamine (formula (17) below) is preferred.

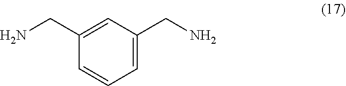

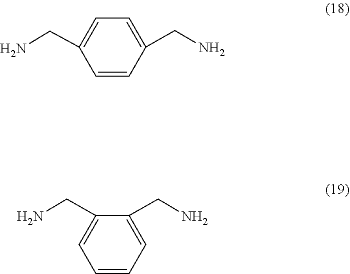 [SMILES: NCc1ccc(CN)cc1 ; NCc1ccccc1CN]

The maleimide compound of this embodiment is not particularly limited as long as it exhibits the effects of the present invention, but from the viewpoints of good solubility in solvents, low melting point, low water absorbency, and good compatibility with other resins, the weight average molecular weight is preferably 100 to 100,000, and more preferably 500 to 30,000. In this embodiment, the “weight average molecular weight” means the weight average molecular weight calculated as a polystyrene standard by gel permeation chromatography (GPC).

Usually, maleimide compounds have poor light transmittance, so when the resin composition described later contains a maleimide compound, light does not reach the photocuring initiator dispersed in the resin composition sufficiently, and the photocuring initiator does not easily generate radicals. Therefore, the photoradical reaction of the maleimide compound generally does not proceed easily, and even if radical polymerization or dimerization reaction of the maleimide alone proceeds, the reactivity of the photoradical reaction of the maleimide compound is very low. However, the maleimide compound according to the present embodiment has very excellent light transmittance because the maleimide group is bonded to the aromatic ring via a methylene group and has a short conjugation length, so that light reaches the photocuring initiator sufficiently and the photoradical reaction of the maleimide occurs efficiently. In addition, when a chloroform solution containing the maleimide compound at 1% by mass is prepared and the light transmittance of this chloroform solution is measured using light of a wavelength of 405 nm (h-rays), the transmittance is 3% or more, which is very excellent light transmittance. Therefore, for example, when a printed wiring board having a high-density and high-definition wiring formation (pattern) is produced by using a direct imaging exposure method, a photoradical reaction of maleimide occurs efficiently even when active energy rays having a wavelength of 405 nm (h-rays) are used.

When active energy rays including a wavelength of 405 nm (h-rays) are used, polymerization does not proceed unless the photocuring initiator absorbs light of a wavelength of 405 nm (h-rays) and generates radicals. Therefore, when active energy rays including a wavelength of 405 nm (h-rays) are used, it is preferable to use a photocuring initiator having an absorbance of 0.1 or more at a wavelength of 405 nm (h-rays) and exhibiting very excellent absorbency for light of a wavelength of 405 nm (h-rays) as the photocuring initiator described below.

Since the maleimide compound of this embodiment has excellent light transmittance as described above, even when light having a wavelength of 405 nm is used, the light sufficiently reaches the photocuring initiator, and a radical reaction using radicals generated from the photocuring initiator proceeds, making it possible to photocur even in a resin composition containing a large amount of the maleimide compound.

Furthermore, the cured product obtained by containing the resin composition of this embodiment has excellent photocurability, heat resistance, and thermal stability, and can therefore be suitably used to form a protective film and an insulating layer.

In the formula (2), B is independently a divalent hydrocarbon group having 6 to 200 carbon atoms, preferably 8 to 100 carbon atoms, more preferably 10 to 50 carbon atoms. Among them, it is preferable that the divalent hydrocarbon group is a branched divalent hydrocarbon group in which one or more hydrogen atoms in the divalent hydrocarbon group are substituted with an alkyl group or an alkenyl group having 6 to 200 carbon atoms or more, preferably 8 to 100 carbon atoms, more preferably 10 to 50 carbon atoms. The branched divalent hydrocarbon group may be either a saturated aliphatic hydrocarbon group or an unsaturated hydrocarbon group, and may have an alicyclic structure or an aromatic ring structure in the middle of the molecular chain. Specific examples of the branched divalent hydrocarbon group include a hydrocarbon group derived from diamines at both ends, called dimer diamine. Note that dimer diamine is a dimer of an unsaturated fatty acid such as oleic acid, in which two carboxy groups of a dimer acid are substituted with primary amino groups, as shown in the following formulas (20) to (25) (see JPA1997-12712). Specific examples of commercially available dimer diamines include PRIAMINE (registered trademark) 1074 and PRIAMINE (registered trademark) 1075 (both manufactured by Croda Japan Co., Ltd.), and Versamine 551 (manufactured by Cognis Japan Co., Ltd.). These may be used alone or in combination of two or more. Non-limiting general formulae of dimer diamines are shown below. In each formula, m+n is preferably 6 to 17, p+q is preferably 8 to 19, and the dashed line represents a carbon-carbon single bond or a carbon-carbon double bond.

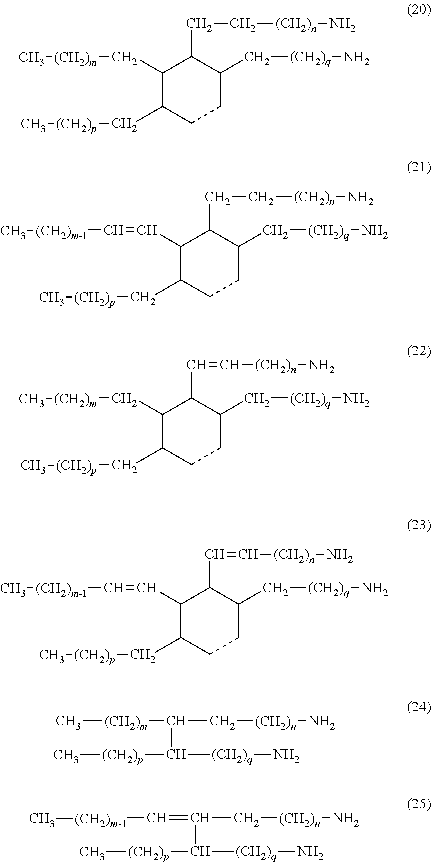

The tetrabasic acid dianhydride (C) used in the synthesis of the bismaleimide resin of the present invention is not particularly limited as long as it has two acid anhydride groups in one molecule. Specific examples of the component (C) include pyromellitic anhydride, ethylene glycol bis(anhydrotrimellitate), glycerin bis(anhydrotrimellitate) monoacetate. 1,2,3,4-butane tetracarboxylic acid dianhydride, 3,3′,4,4′-diphenylsulfone tetracarboxylic acid dianhydride, 3,3′,4,4′-benzophenone tetracarboxylic acid dianhydride, 3,3′,4,4′-biphenyl tetracarboxylic acid dianhydride, 3,3′,4,4′-diphenyl ether tetracarboxylic acid dianhydride, 5-(2,5-dioxotetrahydro-3-furanyl)-3-methylcyclohexene-1,2-dicarboxylic acid anhydride, 3a,4,5,9b-tetrahydro-5-(tetrahydro-2,5-dioxo-3-furanyl)-naphtho[1,2-c]furan-1,3-dione, 1,2,4,5-cyclohexanetetracarboxylic dianhydride, bicyclo(2,2,2)-oct-7-ene-2,3,5,6-tetracarboxylic dianhydride and bicyclo[2.2.2]octane-2,3,5,6-tetracarboxylic dianhydride, 5,5′-((propane-2,2-diylbis(4,1-phenylene))bis(oxy))bis(isobenzofuran-1,3-dione), 4,4′-oxydiphthalic anhydride, 4,4′-(hexafluoroisopropylidene)diphthalic anhydride, and 4,4′-bisphenol A dianhydride. Among them, 4,4′-oxydiphthalic anhydride, 4,4′-(hexafluoroisopropylidene)diphthalic anhydride, and 4,4′-bisphenol A dianhydride are preferred from the viewpoints of solvent solubility and adhesion to a substrate. These may be used alone or in combination of two or more.

The tetrabasic acid dianhydride (C) used in the synthesis of the bismaleimide resin of the present invention preferably contains a compound selected from the group consisting of the following formulae (4) to (12), from the viewpoint of the solvent solubility of the finally obtained bismaleimide resin.

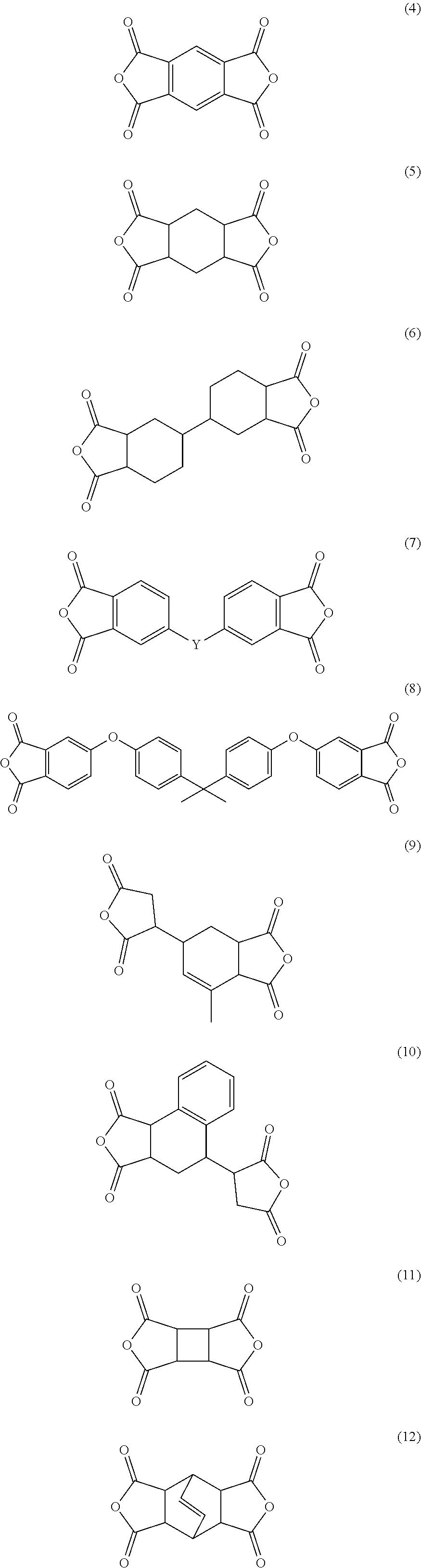

In formula (7), Y represents C(CF₃)₂, SO₂, CO, an oxygen atom, a direct bond, or a divalent linking group represented by the following formula (13).

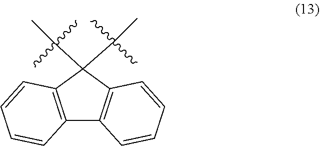 [SMILES: *C1(*)c2ccccc2-c2ccccc21]

In the present invention, the tetrabasic acid dianhydride (C) is preferably a tetrabasic acid dianhydride (C) represented by the following general formula (15).

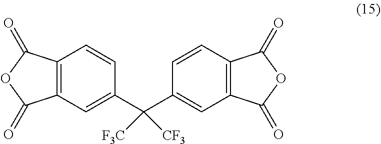

In the present invention, the tetrabasic acid dianhydride (C) is preferably a tetrabasic acid dianhydride (C) represented by the following general formula (8).

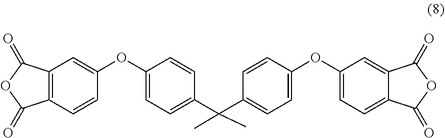

In the present invention, the tetrabasic acid dianhydride (C) is preferably a tetrabasic acid dianhydride (C) represented by the following general formula (5).

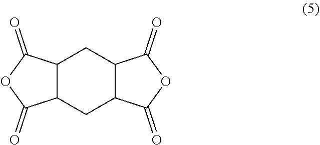

In the present invention, the tetrabasic acid dianhydride (C) is preferably a tetrabasic acid dianhydride (C) represented by the following general formula (9).

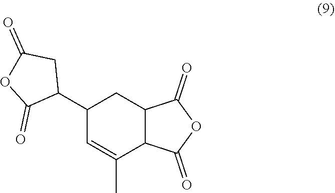

In the present invention, the tetrabasic acid dianhydride (C) is preferably a tetrabasic acid dianhydride (C) represented by the following general formula (10).

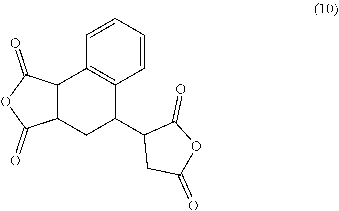

Furthermore, the bismaleimide compound (I) according to the present invention may be a bismaleimide compound obtained by reacting the aromatic diamine (A), an organic diamine (B) other than the aromatic diamine (A), the tetracarboxylic dianhydride (C), and the maleic anhydride. By copolymerizing the organic diamine (B) other than the aromatic diamine (A), it becomes possible to control the required physical properties as required, such as further improving the heat resistance of the obtained cured product.

In the present invention, the organic diamine (B) other than the aromatic diamine (A) (hereinafter, sometimes simply referred to as organic diamine (B)) refers to a diamine other than the diamine contained in the aromatic diamine (A). Such organic diamine (B) is not particularly limited, and examples thereof include: aliphatic diamines such as 1,6-hexamethylenediamine; alicyclic diamines such as 1,4-diaminocyclohexane, 1,3-bis(aminomethyl)cyclohexane, isophoronediamine, and norbomenediamine; aromatic diamines such as 4,4′-diaminodiphenyl ether, 3,4′-diaminodiphenyl ether, 1,4-bis(4-aminophenoxy)benzene, 1,3-bis(aminomethyl)benzene, 1,3-bis(4-aminophenoxy)benzene, 1,3-bis(3-aminophenoxy)benzene, 1,4-diaminobenzene, 1,3-diaminobenzene, 2,4-diaminotoluene, and 4,4′-diaminodiphenylmethane; 4,4′-diaminodiphenyl sulfone; 3,3′-diaminodiphenyl sulfone; 4,4-diaminobenzophenone; 4,4-diaminodiphenyl sulfide; and 2,2-bis[4-(4-aminophenoxy)phenyl]propane. Among them, from the viewpoint of obtaining a cured product having high heat resistance, aliphatic diamines having 6 to 12 carbon atoms such as 1,6-hexamethylenediamine; and diaminocyclohexanes such as 1,3-bis(aminomethyl)cyclohexane, isophoronediamine, and norbomenediamine are more preferred. In addition, when obtaining the bismaleimide compound (I) according to the present invention using these organic diamines (B), these organic diamines (B) may be used alone or in combination of two or more.

The above-mentioned bismaleimide compound (I), particularly the bismaleimide compound (I) having an aromatic ring skeleton, has excellent compatibility with resins having different structures, and is therefore easily used in combination with other resins, and it is easy to complement each other's performance and bring out better performance. Furthermore, the bismaleimide compound of the present invention, particularly the bismaleimide compound having an aromatic ring skeleton, can provide a bismaleimide resin composition that, when molded into a film or substrate, has little variation in curability and physical properties and gives a cured product having a high glass transition point (Tg).

### <Production Method of Bismaleimide Compound (1)>

The production method of the bismaleimide compound (I) is not particularly limited, but it can be produced efficiently by, for example, the method shown below.

The basic flow is that a bismaleimide compound can be obtained by going through step A of synthesizing an amic acid from a tetrabasic acid dianhydride and a diamine, then carrying out ring-closing dehydration, and Step B of reacting the amic acid with maleic anhydride to synthesize maleamic acid, and finally carrying out ring-closing dehydration to cap the molecular chain ends with maleimide groups.

In the above-mentioned production method, each step can be roughly divided into two steps: a synthesis reaction of an amic acid or a maleamic acid, and a ring-closing dehydration reaction, which will be described in detail below.

In step A, a specific tetrabasic acid dianhydride is reacted with a specific diamine to synthesize an amic acid. This reaction generally proceeds in an organic solvent (e.g., a non-polar solvent or a high-boiling aprotic polar solvent) at room temperature (25° C.) to 100° C.

The subsequent ring-closing dehydration reaction of the amic acid is carried out under conditions of 90 to 120° C., and then the water by-produced by the condensation reaction is removed from the system. In order to promote the ring-closing dehydration reaction, an organic solvent (e.g., a non-polar solvent, a high-boiling aprotic polar solvent, etc.) or an acid catalyst can be added.

Examples of the organic solvent include toluene, xylene, anisole, biphenyl, naphthalene. N,N-dimethylformamide (DMF), and dimethyl sulfoxide (DMSO). These may be used alone or in combination of two or more. Examples of the acid catalyst include sulfuric acid, methanesulfonic acid, and trifluoromethanesulfonic acid. These may be used alone or in combination of two or more.

The molar ratio of the diamine to the tetrabasic acid dianhydride is preferably (diamine)/(tetrabasic acid dihydrate)=(2.5 to 1.02)/1.0, and more preferably (diamine)/(tetrabasic acid dianhydride)=(2.0 to 1.15)/1.0. By blending in this ratio, a copolymer containing amino groups at both ends can be synthesized.

In step B, the amic acid having amino groups at both ends obtained in step A is reacted with maleic anhydride at room temperature (25° C.) to 100° C. to synthesize maleamic acid, and finally, the molecular chain ends are blocked with maleimide groups by ring-closing dehydration while removing water by-produced in the system at 95 to 120° C. to obtain the desired bismaleimide compound. It is preferable to carry out the blocking reaction of the molecular chain ends with maleimide groups at 120° C. or less, since side reactions and high molecular weight compounds are less likely to occur.

With such a production method, the obtained bismaleimide compound has a block copolymer structure, and therefore the compatibility of the synthesized resin can be made uniform and improved.

The compound of the present invention may be purified by a conventional method, such as reprecipitation.

The composition containing the bismaleimide compound (I) preferably contains a compound capable of reacting with a maleimide group.

The compound capable of reacting with the maleimide group can include one or more selected from the group consisting of maleimide compounds other than the maleimide compound of the present embodiment (hereinafter also referred to as “other maleimide compounds”), cyanate ester compounds, phenol resins, epoxy resins, oxetane resins, benzoxazine compounds, carbodiimide compounds, and compounds having an ethylenically unsaturated group.

The bismaleimide compound (I) component is preferably 1 to 99% by mass, more preferably 5 to 95% by mass of the resin solid content of the present invention. Each component of the compound capable of reacting with a maleimide group will be described below.

(Maleimide Compounds Other than Bismaleimide Compound (I))

The other maleimide compounds are not particularly limited as long as they are other than the maleimide compound (I) of the present embodiment and have one or more maleimide groups in the molecule. Specific examples thereof include N-phenylmaleimide. N-cyclohexylmaleimide, N-hydroxyphenylmaleimide, N-anilinophenylmaleimide, N-carboxyphenylmaleimide, N-(4-carboxy-3-hydroxyphenyl)maleimide, 6-maleimidohexanoic acid, 4-maleimidobutyric acid, bis(4-maleimidophenyl)methane, 2,2-bis{4-(4-maleimidophenoxy)-phenyl}propane, 4,4-diphenylmethane bismaleimide, bis(3,5-dimethyl-4-maleimidophenyl)methane, bis(3-ethyl-5-methyl-4-maleimidophenyl)methane, bis(3,5-diethyl-4-maleimidophenyl)methane, phenylmethane maleimide, o-phenylene bismaleimide, m-phenylene bismaleimide, p-phenylene bismaleimide, o-phenylene biscitraconimide, m-phenylene biscitraconimide, p-phenylene biscitraconimide, 2,2-bis(4-(4-maleimidophenoxy)-phenyl)propane, 3,3-dimethyl-5,5-diethyl-4,4-diphenylmethane bismaleimide, 4-methyl-1,3-phenylene bismaleimide, 1,2-bismaleimide ethane, 1,4-bismaleimide butane, 1,5-bismaleimide pentane, 1, 5-bismaleimido-2-methylpentane, 1,6-bismaleimidohexane, 1,6-bismaleimido-(2,2,4-trimethyl)hexane, 1,8-bismaleimido-3,6-dioxaoctane, 1,11-bismaleimido-3,6,9-trioxaundecane, 1,3-bis(maleimidomethyl)cyclohexane, 1,4-bis(maleimidomethyl)cyclohexane, 4,4-diphenyletherbismaleimide, 4,4-diphenylsulfonebismaleimide, 1,3-bis(3-maleimidophenoxy)benzene, 1,3-bis(4-maleimidophenoxy)benzene, 4,4-diphenylmethanebiscitraconimide, 2,2-bis[4-(4-citraconimidophenoxy)phenyl]propane, bis(3,5-dimethyl-4-citraconimidophenyl)methane, bis(3-ethyl-5-methyl-4-citraconimidophenyl)methane, bis(3,5-diethyl-4-citraconimidophenyl)methane, polyphenylmethanemaleimide; maleimide compounds represented by formula (6) such as polyphenylmethanemaleimide; maleimide compounds represented by formula (7), fluorescein-5-maleimide, and prepolymers of these maleimide compounds, or prepolymers of maleimide compounds and amine compounds. These maleimide compounds can be used alone or in a suitable mixture of two or more.

As the other maleimide compound represented by formula (26), commercially available products may be used, for example, BMI-2300 (trade name) manufactured by Daiwa Kasei Kogyo Co., Ltd. As the other maleimide compound represented by formula (27), commercially available products may be used, for example, MIR-3000 (trade name) manufactured by Nippon Kayaku Co., Ltd. As the other maleimide compound represented by formula (28), commercially available products may be used, for example, MIR-5000 (trade name) manufactured by Nippon Kayaku Co., Ltd.

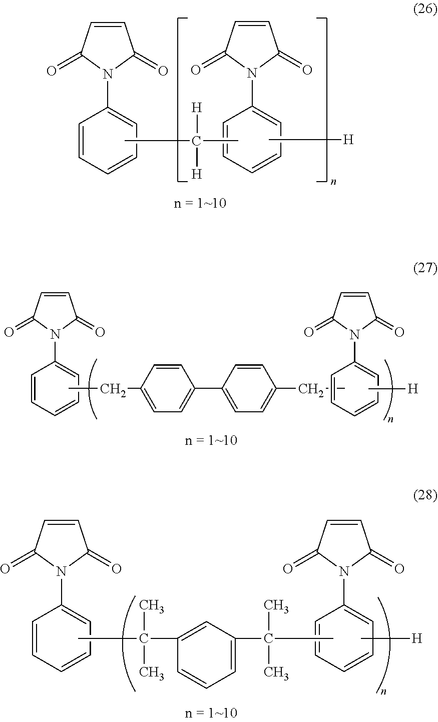

In the composition according to the present embodiment, the total content of the other maleimide compounds is not particularly limited, but is preferably 0.01 to 50 parts by mass per 100 parts by mass of the resin solid content in the composition according to the present embodiment.

### (Cyanate Ester Compound)

The cyanate ester compound is a cyanate ester compound obtained by reacting a phenol resin with a cyanogen halide. Specific examples thereof include dicyanatobenzene, tricyanatobenzene, dicyanatonaphthalene, dicyanatobiphenyl, 2,2′-bis(4-cyanatophenyl)propane, bis(4-cyanatophenyl)methane, bis(3,5-dimethyl-4-cyanatophenyl)methane, 2,2′-bis(3,5-dimethyl-4-cyanatophenyl)propane, 2,2′-bis(4-cyanatophenyl)ethane, 2,2′-bis(4-cyanatophenyl)hexafluoropropane, bis(4-cyanatophenyl)sulfone, bis(4-cyanatophenyl)thioether, phenol novolak cyanate, and phenol-dicyclopentadiene co-condensates in which the hydroxy groups have been converted to cyanate groups, but are not limited thereto.

In addition, the cyanate ester compound, the synthesis method of which is described in JPA2005-264154, is particularly preferred as the cyanate ester compound because of its low moisture absorption, flame retardancy, and excellent dielectric properties.

The cyanate ester compound may contain a catalyst such as zinc naphthenate, cobalt naphthenate, copper naphthenate, lead naphthenate, zinc octylate, tin octylate, lead acetylacetonate, or dibutyltin maleate, in order to trimerize the cyanate group to form a sym-triazine ring, if necessary. The catalyst is used in an amount of usually 0.0001 to 0.10 parts by mass, preferably 0.00015 to 0.0015 parts by mass, per 100 parts by mass of the total mass of the composition.

In the composition according to the present embodiment, the total content of the cyanate ester compounds is not particularly limited, but is preferably 0.01 to 50 parts by mass per 100 parts by mass of the resin solid content in the composition according to the present embodiment.

### (Phenol Resin)

As the phenol resin, as long as it is a phenol resin having two or more hydroxy groups in one molecule, generally known ones can be used. For example, bisphenol A type phenol resin, bisphenol E type phenol resin, bisphenol F type phenol resin, bisphenol S type phenol resin, phenol novolak resin, bisphenol A novolak type phenol resin, glycidyl ester type phenol resin, aralkyl novolak type phenol resin, biphenyl aralkyl type phenol resin, cresol novolak type phenol resin, multifunctional phenol resin, naphthol resin, naphthol novolak resin, multifunctional naphthol resin, anthracene type phenol resin, naphthalene skeleton modified novolak type phenol resin, phenol aralkyl type phenol resin, naphthol aralkyl type phenol resin, dicyclopentadiene type phenol resin, biphenyl type phenol resin, alicyclic phenol resin, polyol type phenol resin, phosphonus-containing phenol resin, polymerizable unsaturated hydrocarbon group-containing phenol resin, and hydroxy group-containing silicone resin can be mentioned, but are not particularly limited. These phenolic resins may be used alone or in combination of two or more.

In the composition according to the present embodiment, the total content of the phenol resin is not particularly limited, but is preferably 0.01 to 50 parts by mass per 100 parts by mass of the resin solid content in the composition according to the present embodiment.

The epoxy resin is not particularly limited, and generally known epoxy resins can be used. For example, bisphenol A type epoxy resins, bisphenol E type epoxy resins, bisphenol F type epoxy resins, bisphenol S type epoxy resins, bisphenol A novolak type epoxy resins, biphenyl type epoxy resins, phenol novolak type epoxy resins, cresol novolak type epoxy resins, xylene novolak type epoxy resins, multifunctional phenol type epoxy resins, naphthalene type epoxy resins, naphthalene skeleton modified novolak type epoxy resins, naphthylene ether type epoxy resins, phenol aralkyl type epoxy resins, anthracene type epoxy resins, trifunctional phenol type epoxy resins, tetrafunctional phenol type epoxy resins, triglycidyl isocyanurate, glycidyl ester type epoxy resin, alicyclic epoxy resin, dicyclopentadiene novolak type epoxy resin, biphenyl novolak type epoxy resin, phenol aralkyl novolak type epoxy resin, naphthol aralkyl novolak type epoxy resin, aralkyl novolak type epoxy resin, naphthol aralkyl type epoxy resin, dicyclopentadiene type epoxy resin, polyol type epoxy resin, phosphorus-containing epoxy resin, glycidylamine, compounds in which the double bonds of butadiene, etc. are epoxidized, compounds obtained by reacting hydroxy group-containing silicone resins with epichlorohydrin, and halides thereof. These epoxy resins can be used alone or in a suitable mixture of two or more.

In the composition according to the present embodiment, the total content of the epoxy resin is not particularly limited, but is preferably 0.01 to 50 parts by mass per 100 parts by mass of the resin solid content in the composition according to the present embodiment.

### (Oxetane Resin)

As the oxetane resin, generally known ones can be used. For example, alkyl oxetanes such as oxetane, 2-methyl oxetane, 2,2-dimethyl oxetane, 3-methyl oxetane, and 3,3-dimethyl oxetane; 3-methyl-3-methoxymethyl oxetane, 3,3-di(trifluoromethyl)perfluoro oxetane, 2-chloromethyl oxetane, 3,3-bis(chloromethyl)oxetane, biphenyl oxetane, OXT-101 (manufactured by Toagosei Co., Ltd., trade name), and OXT-121 (manufactured by Toagosei Co., Ltd., trade name) can be mentioned, but are not particularly limited. These oxetane resins can be used alone or in a suitable mixture of two or more kinds.

In the composition according to this embodiment, the total content of the oxetane resin is not particularly limited, but is preferably 0.01 to 40 parts by mass per 100 parts by mass of the resin solid content in the composition according to this embodiment.

### (Benzoxazine Compound)

As the benzoxazine compound, generally known compounds can be used as long as they have two or more dihydrobenzoxazine rings in one molecule. For example, bisphenol A benzoxazine BA-BXZ (manufactured by Konishi Chemical Co., Ltd., trade name), bisphenol F benzoxazine BF-BXZ (manufactured by Konishi Chemical Co., Ltd., trade name), bisphenol S benzoxazine BS-BXZ (manufactured by Konishi Chemical Co., Ltd., trade name), phenolphthalein benzoxazine, etc. can be mentioned, but are not particularly limited. These benzoxazine compounds can be used alone or in appropriate mixture of two or more kinds.

In the composition according to the present embodiment, the total content of the benzoxazine compounds is not particularly limited, but is preferably 0.01 to 40 parts by mass per 100 parts by mass of the resin solid content in the composition according to the present embodiment.

### (Carbodiimide Compound)

The carbodiimide compound is not particularly limited as long as it has at least one carbodiimide group in the molecule, and generally known compounds can be used. For example, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-o-naphthylcarbodiimide, N,N′-di-2,6-diisopropylphenylcarbodiimide, 2,6,2′,6′-tetraisopropyldiphenvlcarbodiimide, cyclic carbodiimide, Carbodilite (registered trademark: manufactured by Nisshinbo Chemical Inc.), and Stavaxol (registered trademark: manufactured by LANXESS Deutschland GmbH) and other polycarbodiimides can be mentioned. These carbodiimide compounds can be used alone or in a suitable mixture of two or more kinds.

In the composition according to the present embodiment, the total content of the carbodiimide compounds is not particularly limited, but is preferably 0.01 to 40 parts by mass per 100 parts by mass of the resin solid content in the composition according to the present embodiment.

### (Compound Having an Ethylenically Unsaturated Group)

The compound having an ethylenically unsaturated group is not particularly limited as long as it has an ethylenically unsaturated group in one molecule.

Specific examples of compounds having an ethylenically unsaturated group include methyl (meth)acrylate, ethyl (meth)acrylate, butyl (meth)acrylate, lauryl (meth)acrylate, polyethylene glycol (meth)acrylate, polyethylene glycol (meth)acrylate monomethyl ether, phenylethyl (meth)acrylate, isobornyl (meth)acrylate, cyclohexyl (meth)acrylate, benzyl (meth)acrylate, tetrahydrofurfuryl (meth)acrylate, butanediol di(meth)acrylate, hexanediol di(meth)acrylate, neopentyl glycol di(meth)acrylate, nonanediol di(meth)acrylate, glycol di(meth)acrylate, diethylene di(meth)acrylate, polyethylene glycol di(meth)acrylate, tris(meth)acryloyloxyethyl isocyanurate, and polypropylene glycol di(meth)acrylate, adipic acid epoxy di(meth)acrylate, bisphenol ethylene oxide di(meth)acrylate, hydrogenated bisphenol ethylene oxide (meth)acrylate, bisphenol di(meth)acrylate, ε-caprolactone modified hydroxypivalic acid neopen glycol di(meth)acrylate, ε-caprolactone modified dipentaerythritol hexa(meth)acrylate, ε-caprolactone modified dipentaerythritol poly(meth)acrylate, dipentaerythritol poly(meth)acrylate, trimethylolpropane tri(meth)acrylate, triethylolpropane tri(meth)acrylate, and ethylene oxide adducts thereof; pentaerythritol tri(meth)acrylate, and ethylene oxide adducts thereof; pentaerythritol tetra(meth)acrylate, dipentaerythritol hexa(meth)acrylate, and ethylene oxide adducts thereof.

Other specific examples of the compound having an ethylenically unsaturated group include: urethane (meth)acrylates having both a (meth)acryloyl group and a urethane bond in the same molecule; polyester (meth)acrylates having both a (meth)acryloyl group and an ester bond in the same molecule; epoxy (meth)acrylates derived from epoxy resins and having (meth)acryloyl group; and reactive oligomers in which these bonds are used in combination.

Examples of urethane (meth)acrylates include reaction products of hydroxy group-containing (meth)acrylate with polyisocyanate and other alcohols used as necessary. Examples of urethane (meth)acrylates include: hydroxyalkyl (meth)acrylates such as hydroxyethyl (meth)acrylate, hydroxypropyl (meth)acrylate, and hydroxybutyl (meth)acrylate; glycerin (meth)acrylates such as glycerin mono(meth)acrylate and glycerin di(meth)acrylate; and urethane (meth)acrylates obtained by reacting sugar alcohol (meth)acrylates, such as pentaerythritol di(meth)acrylate, pentaerythritol tri(meth)acrylate, dipentaerythritol penta(meth)acrylate, dipentaerythritol hexa(meth)acrylate, etc., with polyisocyanates, such as toluene diisocyanate, hexamethylene diisocyanate, trimethylhexamethylene diisocyanate, isophorone diisocyanate, norbomene diisocyanate, xylene diisocyanate, hydrogenated xylene diisocyanate, dicyclohexanemethylene diisocyanate, and isocyanurates thereof, and biuret reaction products.

Examples of polyester (meth)acrylates include: monofunctional (poly)ester (meth)acrylates such as caprolactone-modified 2-hydroxyethyl (meth)acrylate, ethylene oxide and/or propylene oxide-modified phthalic acid (meth)acrylate, ethylene oxide-modified succinic acid (meth)acrylate, and caprolactone-modified tetrahydrofurfuryl (meth)acrylate; di(poly)ester (meth)acrylates such as hydroxypivalic acid ester neopentyl glycol di(meth)acrylate, caprolactone-modified hydroxypivalic acid ester neopentyl glycol di(meth)acrylate, and epichlorohydrin-modified phthalic acid di(meth)acrylate; and mono-, di-, or tri(meth)acrylates of triols obtained by adding 1 mole or more of a cyclic lactone compound such as ε-caprolactone, γ-butyrolactone, or δ-valerolactone to 1 mole of trimethylolpropane or glycerin.

Further examples include: mono-, di-, tri-, or tetra(meth)acrylates of triols obtained by adding 1 mole or more of a cyclic lactone compound such as ε-caprolactone, γ-butyrolactone, δ-valerolactone, etc. to 1 mole of pentaerythritol, dimethylolpropane, trimethylolpropane, or tetramethylolpropane; mono- or poly(meth)acrylates of triols obtained by adding 1 mole or more of a cyclic lactone compound such as ε-caprolactone, γ-butyrolactone, δ-valerolactone, etc. to 1 mole of dipentaerythritol, and mono- or poly(meth)acrylates of polyhydric alcohols such as triols, tetraols, pentaols, or hexaols.

Further examples include: (meth)acrylates of polyester polyols which are reaction products of diol components such as (poly)ethylene glycol, (poly)propylene glycol, (poly)tetramethylene glycol, (poly)butylene glycol, 3-methyl-1,5-pentanediol, and hexanediol, with polybasic acids such as maleic acid, fumaric acid, succinic acid, adipic acid, phthalic acid, isophthalic acid, hexahydrophthalic acid, tetrahydrophthalic acid, dimer acid, sebacic acid, azelaic acid, and 5-sodium sulfoisophthalic acid, and anhydrides thereof; and polyfunctional (poly)ester (meth)acrylates such as (meth)acrylates of cyclic lactone-modified polyester diols consisting of diol components, polybasic acids, anhydrides thereof, and cyclic lactone such as ε-caprolactone, γ-butyrolactone, δ-valerolactone, and the like.

Epoxy (meth)acrylates are carboxylate compounds of compounds having epoxy groups and (meth)acrylic acid. Examples of epoxy (meth)acrylates include phenol novolak epoxy (meth)acrylates, cresol novolak epoxy (meth)acrylates, trishydroxyphenylmethane epoxy (meth)acrylates, dicyclopentadienephenol epoxy (meth)acrylates, bisphenol A epoxy (meth)acrylates, bisphenol F epoxy (meth)acrylates, biphenol epoxy (meth)acrylates, bisphenol A novolak epoxy (meth)acrylates, naphthalene skeleton-containing epoxy (meth)acrylates, glyoxal epoxy (meth)acrylates, heterocyclic epoxy (meth)acrylates, and their acid anhydride-modified epoxy acrylates.

Specific examples of the compound having an ethylenically unsaturated group include vinyl ethers such as ethyl vinyl ether, propyl vinyl ether, hydroxyethyl vinyl ether, and ethylene glycol divinyl ether; styrenes such as styrene, methylstyrene, ethylstyrene, and divinylbenzene; and compounds having a vinyl group such as triallyl isocyanurate, trimethallyl isocyanurate, and bisallylnadimide.

As the compound having an ethylenically unsaturated group, commercially available products can be used, and examples thereof include KAYARAD (registered trademark) ZXR-801H (trade name, manufactured by Nippon Kay aku Co., Ltd.), and propylene glycol monomethyl ether acetate of dicyclopentadiene type epoxy acrylate compound (KAYARAD (registered trademark) ZXR-1806H (trade name), KAYARAD (registered trademark) ZXR-1810H (trade name), and KAYARAD (registered trademark) ZXR-1889H (trade name), manufactured by Nippon Kayaku Co., Ltd.). These compounds having an ethylenically unsaturated group can be used alone or in appropriate mixture of two or more types.

In the composition according to the present embodiment, the total content of the compounds having an ethylenically unsaturated group is not particularly limited, but is preferably 0.01 to 60 parts by mass per 100 parts by mass of the resin solid content in the composition according to the present embodiment.

The composition contains components other than the compound represented by the general formula (2). Examples of other components contained in the resin composition include organic solvents, photopolymerization initiators, curing agents having reactive groups capable of reacting with maleimide groups, and adhesion enhancers such as curing catalysts or coupling agents, and fillers. Various other components can be used without particular limitation according to the application and method of use of the resin composition. Resin compositions containing organic solvents are preferred because they are easy to handle.

In addition, the compound of the present invention can be used without using photopolymerization initiators, curing agents, curing catalysts, etc. because it is capable of self-polymerization reaction.

### (Photopolymerization Initiator)

The bismaleimide compound represented by the general formula (2) can self-polymerize by itself, but it can also be self-polymerized after forming a composition by using a photopolymerization initiator or a curing catalyst in combination with the compound represented by the general formula (2). By using a photopolymerization initiator in combination, it becomes possible to self-polymerize by irradiation with light, and by using a curing catalyst in combination, it is possible to lower the heating temperature during self-polymerization compared to when no curing catalyst is used.

The photopolymerization initiator that can be used in combination with the self-polymerization is not particularly limited, and any conventionally used initiator can be appropriately used. Specific examples of the photopolymerization initiator include acetophenone, 2,2-dimethoxyacetophenone, p-dimethylaminoacetophenone, Michler's ketone, benzil, benzoin, benzoin methyl ether, benzoin ethyl ether, benzoin isopropyl ether, benzoin n-propyl ether, benzoin isopropyl ether, benzoin n-butyl ether, benzyl dimethyl ketal, thioxanthone, 2-chlorothioxanthone, 2-methylthioxanthone, 2,2-dimethoxy-1,2-diphenylethane-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, 2-methyl-1-(4-methylthiophenyl)-2-morpholinopropan-1-one, 2-benzyl-2-dimethylamino-1-(4-morpholinophenyl)-1-butanone, 2,4,6-trimethylbenzoyl-diphenyl-phosphine oxide, bis(2,4,6-trimethylbenzoyl)-phenylphosphine oxide, 1-[4-(phenylthio)phenyl]-1,2-octanedione=2-(O-benzoyloxime), 1-[9-ethyl-6-(2-methylbenzoyl)-9H-carbazol-3-yl]ethanone 1-(O-acetyloxime), and 2,4-dimethylthioxanthone. These photopolymerization initiators may be used alone or in combination of two or more.

Among these, from the viewpoint of enabling fine pattern formation using a reduction projection exposure machine (stepper; light source wavelength: 365 nm, 436 nm) that is standardly used in the manufacturing process of semiconductor protective films and the like, it is preferable to use one that efficiently generates radicals at an exposure wavelength of 310 nm to 436 nm (more preferably 365 nm). Preferred examples of the photopolymerization initiator include 1-[4-(phenylthio)phenyl]-1,2-octanedione=2-(0-benzoyloxime) (manufactured by BASF Japan, “IRGACURE OXE-01”), 1-[9-ethyl-6-(2-methylbenzoyl)-9H-carbazol-3-yl]ethanone 1-(O-acetyloxime) (manufactured by BASF Japan, “IRGACURE OXE-02”), 2,4-dimethylthioxanthone (manufactured by Nippon Kayaku Co., Ltd., “DETX-S”), and 2-methyl-1-[4-(methylthio)phenyl]-2-morpholinopropan-1-one (manufactured by IGM Resins B.V., “Omirad 907”).

The amount of the photopolymerization initiator used is preferably 0.1 to 20 parts by mass, more preferably 1 to 5 parts by mass, based on 100 parts by mass of the compound represented by formula (1).

A sensitizer may be used in combination with the photopolymerization initiator. The sensitizer that can be used in combination is not particularly limited as long as it is a conventionally known sensitizer, and examples thereof include 4,4′-bis(diethylamino)benzophenone.

The amount of the sensitizer used is preferably 2 parts by mass or less, more preferably 0.05 parts by mass to 0.5 parts by mass, based on 100 parts by mass of the compound represented by formula (2). By using a sensitizer in combination, the sensitivity to light during self-polymerization can be increased.

### (Curing Catalyst)

The curing catalyst that can be used in combination during self-polymerization is not particularly limited as long as it can promote the self-polymerization of the maleimide groups at both ends of the compound represented by formula (1) of the present invention by heating, and conventionally used catalysts can be appropriately adopted. Specific examples of the curing catalyst include imidazoles such as 2-methylimidazole, 2-ethylimidazole, 2-phenylimidazole, 2-ethyl-4-methylimidazole, 2-undecylimidazole, and 1-cyanoethyl-2-ethyl-4-methylimidazole; amines such as triethylamine, triethylenediamine, 2-(dimethylaminomethyl)phenol, 1,8-diaza-bicyclo(5,4,0)undecene-7, tris(dimethylaminomethyl)phenol, and benzyldimethylamine; phosphines such as triphenylphosphine, tributylphosphine, and trioctylphosphine; organic metals such as tin octylate, zinc octylated, dibutyltin dimaleate, zinc naphthenate, cobalt naphthenate, and tin oleate; metal chlorides such as zinc chloride, aluminum chloride, and tin chloride; organic peroxides such as di-tert-butyl peroxide and dicumyl peroxide; azo compounds such as azobisisobutyronitrile and azobisdimethylvaleronitrile; mineral acids such as hydrochloric acid, sulfuric acid, and phosphoric acid; Lewis acids such as boron trifluoride; and salts such as sodium carbonate and lithium chloride.

The amount of the curing catalyst used is preferably 10 parts by mass or less, more preferably 1 part by mass to 5 parts by mass, based on 100 parts by mass of the compound represented by formula (1).

The curing agent according to the present invention is not particularly limited, and a conventionally used compound can be appropriately adopted. The curing agent is not particularly limited as long as it is a compound having a functional group (or structure) capable of crosslinking with a maleimide compound, such as an amino group, a cyanate group, a phenolic hydroxy group, or an alcoholic hydroxy group. In addition, a maleimide compound other than the maleimide compound according to the present invention may be used in combination.

### (Organic Solvent)

The organic solvent is not particularly limited, but examples thereof include γ-butyrolactone, ethyl lactate, propylene glycol monomethyl ether acetate, benzyl acetate, n-butyl acetate, ethoxyethyl propionate, 3-methylmethoxypropionate, N-methyl-2-pyrrolidone, N-ethyl-2-pyrrolidone, N,N-dimethylformamide, N,N-dimethylacetamide, dimethylsulfoxide, hexamethylphosphorylamide, tetramethylene sulfone, cyclohexanone, cyclopentanone, diethyl ketone, diisobutyl ketone, and methyl amyl ketone. These organic solvents can be used alone or in combination of two or more. The use of an organic solvent in combination is a preferred embodiment in terms of improving the handling of the composition.

There is no particular limit to the content of the organic solvent in the composition of the present invention, but the content of the solvent in the composition is usually 95% by mass or less, preferably 20% by mass to 90% by mass.

### (Coupling Agent)

Examples of the silane coupling agent include, but are not limited to, 3-chloropropyltrimethoxysilane, vinyltrichlorosilane, vinyltriethoxysilane, vinyltrimethoxysilane, vinyl-tris(2-methoxyethoxy)silane, 3-methacryloxypropyltrimethoxysilane, 2-(3,4-epoxycyclohexyl)ethyltrimethoxysilane, 3-glycidoxypropyltrimethoxysilane, 3-mercaptopropyltrimethoxysilane, 3-aminopropyltriethoxysilane, N-2-(aminoethyl)-3-aminopropyltrimethoxysilane, and 3-ureidopropyltriethoxysilane. These can be used alone or in combination of two or more.

Since the silane coupling agent is unreactive with the compound of the present invention (compound, self-polymerizing compound, benzoxazole), components other than those acting at the substrate interface may remain as residual components after curing. Therefore, the use of a large amount of the adhesion enhancer may have adverse effects such as a decrease in physical properties. Depending on the type of substrate, even a small amount can be effective, so it is appropriate to use it within a range that does not have a negative effect. The usage ratio is usually 15 mass % or less, and preferably more than 0 mass % and 5 mass % or less, based on the composition, but the upper limit of the usage ratio may vary depending on the type of substrate.

### (Thermoplastic Resin)

Examples of the thermoplastic resin include polyethersulfone, polystyrene, polycarbonate, etc. Examples of the colorant include phthalocyanine blue, phthalocyanine green, iodine green, crystal violet, titanium oxide, carbon black, naphthalene black, etc. Examples of the thickener include orben, bentone, montmorillonite, etc. Examples of the thermal polymerization inhibitor include hydroquinone, 2,6-di-tert-butyl-p-methylphenol, etc. Examples of the defoamer include silicone-based, fluorine-based, and polymer-based defoamers.

The amount of these additives used in the composition of the present invention is preferably 30% by mass or less, for example, as a rough guideline, but may be increased or decreased as appropriate depending on the purpose of use.

### (Filler)

The resin composition of the present embodiment may further contain a filler in order to improve various properties such as coating properties, heat resistance, etc. It is preferable that the filler has insulating properties and does not inhibit the transparency to light with a wavelength of 405 nm (h-rays). The filler is not particularly limited, but examples thereof include silica (e.g., natural silica, fused silica, amorphous silica, hollow silica, etc.), aluminum compounds (e.g., boehmite, aluminum hydroxide, alumina, aluminum nitride, etc.), boron compounds (e.g., boron nitride, etc.), magnesium compounds (e.g., magnesium oxide, magnesium hydroxide, etc.), calcium compounds (e.g., calcium carbonate, etc.), molybdenum compounds (e.g., molybdenum oxide, zinc molybdate, etc.), barium compounds (e.g., barium sulfate, barium silicate, etc.), talc (e.g., natural talc, calcined talc, etc.), mica, glass (e.g., short fiber glass, spherical glass, fine powder glass (e.g., E glass, T glass, D glass, etc.), etc.), silicone powder, fluororesin-based fillers, urethane resin-based fillers. (meth)acrylic resin-based fillers, polyethylene-based fillers, styrene-butadiene rubber, and silicone rubber. These fillers can be used alone or in a suitable mixture of two or more.

Among them, it is preferable to use one or more selected from the group consisting of silica, boehmite, barium sulfate, silicone powder, fluororesin-based fillers, urethane resin-based fillers. (meth)acrylic resin-based fillers, polyethylene-based fillers, styrene-butadiene rubber, and silicone rubber.

These fillers may be surface-treated with a silane coupling agent or the like described below.

From the viewpoints of improving the heat resistance of the cured product obtained by curing the resin composition of this embodiment and obtaining good coating properties, silica is preferred, and fused silica is more preferred. Specific examples of silica include SFP-130MC manufactured by Denka Co., Ltd., and SC2050-MB, SC1050-MLE, YA010C-MFN, and YA050C-MJA manufactured by Admatechs Co., Ltd.

The particle size of the filler is not particularly limited, but is usually 0.005 to 100 μm, and preferably 0.01 to 50 μm.

In the resin composition of the present embodiment, the content of the filler is not particularly limited, but from the viewpoint of improving the heat resistance of the cured product, it is preferably 1000 parts by mass or less, more preferably 500 parts by mass or less, and most preferably 300 parts by mass or less, relative to 100 parts by mass of the resin solid content in the resin composition. In addition, when a filler is contained, the lower limit is not particularly limited, but from the viewpoint of obtaining an effect of improving various properties such as coating property and heat resistance, it is usually 1 part by mass relative to 100 parts by mass of the resin solid content in the resin composition.

Examples of other components that may be contained in the resin composition of the present invention include various additives such as colorants, thickeners, thermal polymerization inhibitors, antifoaming agents, and leveling agents.

The cured product containing the bismaleimide compound (I) is obtained by curing the resin composition of this embodiment. The cured product is not particularly limited, but can be obtained, for example, by melting or dissolving the resin composition in a solvent, pouring it into a mold, and curing it under normal conditions using heat, light, or the like. In the case of heat curing, the curing temperature is not particularly limited, but is preferably within the range of 120° C. to 300° C. from the viewpoint of efficient curing and preventing deterioration of the obtained cured product. In the case of photocuring, the wavelength region of the light is not particularly limited, but it is preferable to cure in the range of 100 nm to 500 nm, where curing proceeds efficiently by a photopolymerization initiator, etc.

The heat-resistant resin coating film formed by the resin composition of the present invention can be used in electronic parts such as semiconductor devices and multilayer wiring boards, and organic EL display devices. Specifically, it is suitably used for applications such as passivation films for semiconductors, surface protective films for semiconductor elements, interlayer insulating films, insulating films for rewiring lavers, interlayer insulating films for multilayer wiring for high-density mounting, interlayer insulating films for electronic parts such as inductors and SAW filters, and insulating films and flat layers for organic electroluminescent devices, but is not limited thereto, and can have various structures.

The compound and composition of the present invention can also be used in the form of a dry film resist. That is, the compound and composition of the present invention can be applied to a base film using a roll coater, die coater, knife coater, bar coater, gravure coater, or the like, and then dried in a drying oven set at 45° C. to 140° C. to remove a predetermined amount of solvent, and a cover film or the like can be laminated as necessary to form a dry film resist. In this case, the thickness of the resist on the base film is adjusted to 2 μm to 200 μm. As the base film and cover film, for example, films of polyester, polypropylene, polyethylene, TAC, polyimide, or the like are used. These films may be treated with a silicone-based release agent or a non-silicone-based release agent as necessary. If supplied as a dry film resist, it is possible to omit the steps of application to a support and drying, and the photosensitive resin composition of the present invention can be used more easily.

### EXAMPLES

The present invention will be described in more detail below based on examples and comparative examples, but the present invention is not limited to the following examples. In the examples, “parts” and “%” are based on mass. In the examples and comparative examples, the compatibility, dielectric properties, and heat resistance (glass transition temperature (Tg)) were evaluated as follows.

The molecular weight measurement conditions were as follows.
Model: GPC TOSOH HLC-8220 GPC
Column: Super HZM-N
Eluent: THF (tetrahydrofuran); 0.35 ml/min, 40° C.
Detector: RI (differential refractometer)
Molecular weight standard: polystyrene

### Synthesis Example 1 (I-1)

162 g of toluene and 162 g of N-methylpyrrolidone were charged to a 1 L round bottom flask equipped with a thermometer, reflux condenser, Dean-Stark apparatus, powder inlet, nitrogen inlet, and stirrer. 32.4 g (0.24 mol) of metaxylenediamine (Mitsubishi Gas Chemical Co., Ltd.) was then added, followed by the slow addition of 22.9 g (0.24 mol) of methanesulfonic acid to form the salt. The mixture was stirred for approximately 10 minutes to mix, and then 4,4′-(hexafluoroisopropylidene)diphthalic anhydride (52.8 g, 0.12 mol) was slowly added to the stirred mixture. The mixture was heated to reflux for 6 hours to form the amine-terminated diimide. The theoretical amount of water produced from this condensation had been reached by this time. The reaction mixture was cooled to below room temperature and 28.0 g (0.29 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, yielding a varnish of the bismaleimide compound. The varnish was then dropped into 1,000 g of methanol to carry out a reprecipitation step, and the solvent was removed and dried to obtain 78 g of the desired bismaleimide compound as a light brown solid (yield 78%, Mw=3,600) (1-1).

### Synthesis Example 2 (1-2)

165 g of toluene and 165 g of N-methylpyrrolidone were added to a 1 L round bottom flask equipped with a thermometer, reflux condenser, Dean-Stark apparatus, powder inlet, nitrogen inlet, and stirrer. Next, 26.6 g (0.20 mol) of metaxylenediamine (Mitsubishi Gas Chemical Co., Ltd.) and 11.7 g (0.02 mol) of dimer diamine (PRIAMINE(Registered trademark) 1075, Croda Japan Co., Ltd.) were added, followed by the slow addition of 20.9 g (0.22 mol) of methanesulfonic acid to form the salt. The mixture was stirred for approximately 10 minutes to mix, and then 4,4′-(hexafluoroisopropylidene)diphthalic anhydride (48.2 g, 0.11 mol) was slowly added to the stirred mixture. The mixture was heated to reflux for 6 hours to form the amine-terminated diimide. The theoretical amount of water produced from this condensation was obtained by this time. The reaction mixture was cooled below room temperature, and 25.5 g (0.26 mol) of maleic anhydride was added to the flask. The mixture was refluxed for an additional 8 hours to obtain the expected amount of water produced. After cooling to room temperature, the organic layer was washed with water (100 ml×5 times) to remove salts and unreacted raw materials, obtaining a varnish of the bismaleimide compound. The varnish was then dropped into 1,000 g of methanol to perform a reprecipitation step, and the solvent was removed and dried to obtain 72 g (yield 72%, Mw=4.000) of the desired light brown solid bismaleimide compound (1-2).

### Synthesis Example 3 (I-3)

165 g of toluene and 165 g of N-methylpyrrolidone were charged to a 1 L round bottom flask equipped with a thermometer, reflux condenser, Dean-Stark apparatus, powder inlet, nitrogen inlet, and stirrer. 29.7 g (0.22 mol) of metaxylenediamine (Mitsubishi Gas Chemical Co., Ltd.) was then added, followed by the slow addition of 21.0 g (0.22 mol) of methanesulfonic acid to form the salt. After approximately 10 minutes of stirring to mix, 4,4′-bisphenol A dianhydride (56.8 g, 0.11 mol) was slowly added to the stirred mixture. The mixture was heated to reflux for 6 hours to form the amine-terminated diimide. The theoretical amount of water produced from this condensation had been reached by this time. The reaction mixture was cooled to below room temperature and 25.7 g (0.26 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, yielding a varnish of the bismaleimide compound. The varnish was then dropped into 1,000 g of methanol to carry out a reprecipitation step, and the solvent was removed and dried to obtain 78 g of the desired bismaleimide compound as a light brown solid (yield 80%, Mw=4,500) (1-3).

### Synthesis Example 4 (1-4)

150 g of toluene and 150 g of N-methylpyrrolidone were charged to a 1 L round bottom flask equipped with a thermometer, reflux condenser, Dean-Stark apparatus, powder inlet, nitrogen inlet, and stirrer. 43.9 g (0.32 mol) of metaxylenediamine (Mitsubishi Gas Chemical Co., Ltd.) was then added, followed by the slow addition of 31.0 g (0.32 mol) of methanesulfonic acid to form the salt. The mixture was stirred for approximately 10 minutes to mix, and then 1,2,4,5-cyclohexanetetracarboxylic dianhydride (36.1 g, 0.16 mol) was slowly added to the stirred mixture. The mixture was heated to reflux for 6 hours to form the amine-terminated diimide. The theoretical amount of water produced from this condensation had been reached by this time. The reaction mixture was cooled to below room temperature, and 37.9 g (0.38 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, yielding a varnish of the bismaleimide compound. The varnish was then dropped into 1,000 g of methanol to carry out a reprecipitation step, and the solvent was removed and dried to obtain 78 g of the desired white solid bismaleimide compound (yield 78%, Mw=3,000) (I4).

### Synthesis Example 5 (1-5)

150 g of toluene and 150 g of N-methylpyrrolidone were charged to a 1 L round bottom flask equipped with a thermometer, reflux condenser, Dean-Stark apparatus, powder inlet, nitrogen inlet, and stirrer. 41.2 g (0.30 mol) of metaxylenediamine (Mitsubishi Gas Chemical Co., Ltd.) was then added, followed by the slow addition of 29.1 g (0.30 mol) of methanesulfonic acid to form the salt. The mixture was stirred for approximately 10 minutes to mix, and then 5-(2,5-dioxotetrahydrofuryl)-3-methyl-3-cyclohexene-1,2-dicarboxylic dianhydride (40.0 g, 0.15 mol) was slowly added to the stirred mixture. The mixture was heated to reflux for 6 hours to form the amine-terminated diimide. The theoretical amount of water produced from this condensation was reached by this time. The reaction mixture was cooled below room temperature, and 35.6 g (0.36 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, and a vamish of the bismaleimide compound was obtained. The varnish was then dropped into 1,000 g of methanol to perform a reprecipitation process, and the solvent was removed and dried to obtain 75 g (yield 75%. Mw=3,500) of the desired white solid bismaleimide compound (I-5).

### Synthesis Example 6 (1-6)

154 g of toluene and 154 g of N-methylpyrrolidone were charged to a 1 L round bottom flask equipped with a thermometer, reflux condenser, Dean-Stark apparatus, powder inlet, nitrogen inlet, and stirrer. 39.1 g (0.28 mol) of metaxylenediamine (Mitsubishi Gas Chemical Co., Ltd.) was then added, followed by the slow addition of 27.6 g (0.28 mol) of methanesulfonic acid to form the salt. The mixture was stirred for approximately 10 minutes 10 to mix, and then 4-(2,5-dioxotetrahydrofuran-3-yl)-1,2,3,4-tetrahydronaphthalene-1,2-dicarboxylic anhydride (43.1 g, 0.14 mol) was slowly added to the stirred mixture. The mixture was heated to reflux for 6 hours to form the amine-terminated diimide. The theoretical amount of water produced from this condensation was reached by this time. The reaction mixture was cooled below room temperature, and 33.8 g (0.34 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, and a varnish of a bismaleimide compound was obtained. The varnish was then dropped into 1,000 g of methanol to perform a reprecipitation process, and the solvent was removed and dried to obtain 75 g (yield 75%, Mw=3,200) of the desired white solid bismaleimide compound (I-6).

### Comparative Synthesis Example 1 (BMI-1) A

500 ml round bottom flask equipped with a fluororesin coated stir bar was charged with 110 g toluene and 36 g N-methylpyrrolidone. Next, 90.9 g (0.17 mol) of dimer diamine (PRIAMINE(Registered trademark) 1075, Croda Japan Co., Ltd.) was added, followed by the slow addition of 16.4 g (0.17 mol) of methanesulfonic anhydride to form the salt. The mixture was stirred for approximately 10 minutes to mix, and then pyromellitic anhydride (18.6 g, 0.08 mol) was slowly added to the stirred mixture. A Dean-Stark trap and condenser were attached to the flask. The mixture was heated to reflux for 6 hours to form the amine-terminated diimide. The theoretical amount of water produced from this condensation had been obtained by this time. The reaction mixture was cooled to below room temperature and 20.0 g (0.20 mol) of maleic anhydride was added to the flask. The mixture was refluxed for an additional 8 hours to obtain the expected amount of water produced. After cooling to room temperature, an additional 200 ml of toluene was added to the flask. The diluted organic laver was then washed with water (100 ml×3 times) to remove salts and unreacted raw materials. The solvent was then removed under vacuum to obtain 102 g (yield 85%, Mw=3,800) of a brown waxy bismaleimide compound.

The bismaleimide compound of Comparative Synthesis Example 1 represented by the following formula is readily available from Designer Molecules Inc. under the trade name “BMI-3000.”

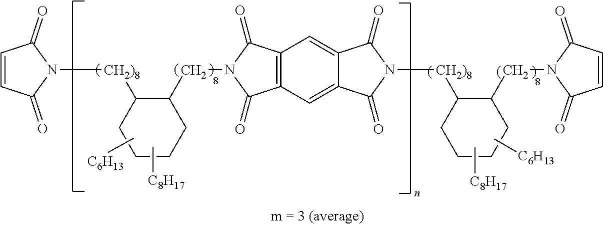

### Comparative Synthesis Example 2 (BMI-2) A

500 ml round bottom flask equipped with a fluororesin coated stir bar was charged with 110 g toluene and 36 g N-methylpyrrolidone. Next, 85.3 g (0.16 mol) of dimer diamine (PRIAMINE® 1075, Croda Japan Co., Ltd.) was added, followed by the slow addition of 15.4 g (0.16 mol) of methanesulfonic anhydride to form the salt. The mixture was stirred for approximately 10 minutes to mix, and then 4,4′-oxydiphthalic dianhydride (24.8 g, 0.08 mol) was slowly added to the stirred mixture. A Dean-Stark trap and condenser were attached to the flask. The mixture was heated to reflux for 6 hours to form the amine-terminated diimide. The theoretical amount of water produced from this condensation was obtained by this time. The reaction mixture was cooled below room temperature, and 18.8 g (0.19 mol) of maleic anhydride was added to the flask. The mixture was refluxed for an additional 8 hours, yielding the expected amount of water produced. After cooling to room temperature, an additional 200 ml of toluene was added to the flask. The diluted organic layer was then washed with water (100 ml×3 times) to remove salts and unreacted raw materials. The solvent was then removed under vacuum, yielding 106 g (yield 88%, Mw=3,700) of a brown waxy bismaleimide compound.

The bismaleimide compound of Comparative Synthesis Example 2 represented by the following formula is readily available from Designer Molecules Inc. under the trade name “BMI-1500”.

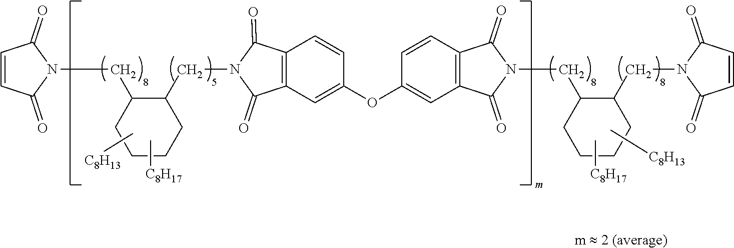

### Comparative Synthesis Example 3 (BMI-3)

Bismaleimide compound (BMI-3) was synthesized by a known method using the method described in Example 1 of JPA2021-123672.

2 L glass four-neck flask equipped with a stirrer, a Dean-Stark tube, a cooling condenser, and a thermometer was added with 37.25 g (0.219 mol) of isophoronediamine, 76.94 g (0.35 mol) of pyromellitic anhydride, and 350 g of toluene, and amic acid was synthesized by stirring at 80° C. for 3 hours. Thereafter, the mixture was heated to 110° C. and stirred for 4 hours while distilling off the by-product water, to synthesize a block copolymer.

Thereafter, 116.88 g (0.219 mol) of dimer diamine (PRIAMINE (registered trademark) 1075, manufactured by Croda Japan Co., Ltd.) was added to the flask containing the block copolymer solution cooled to room temperature, and the mixture was stirred at 80° C. for 3 hours to synthesize an amic acid. Thereafter, the mixture was heated to 110° C. as it was, and stirred for 4 hours while distilling off the by-product water, to synthesize a both ends diamine.

The flask containing the obtained both ends diamine solution was cooled to room temperature, and then 18.88 g (0.193 mol) of maleic anhydride was added, and the mixture was heated again and stirred at 80° C. for 3 hours to synthesize an amic acid. Thereafter, the mixture was heated to 110° C. as it was, and stirred for 15 hours while distilling off the by-product water, and washed with 300 g of water five times to obtain a vamish of a bismaleimide compound. Thereafter, the varnish was dropped into 3,000 g of isopropyl alcohol (IPA) to carry out a reprecipitation process, and the solvent was removed and the solid was dried to obtain the target dark brown solid (yield 85%, Mw=8,000).

The bismaleimide compound of Comparative Synthesis Example 3 is represented by the following formula.

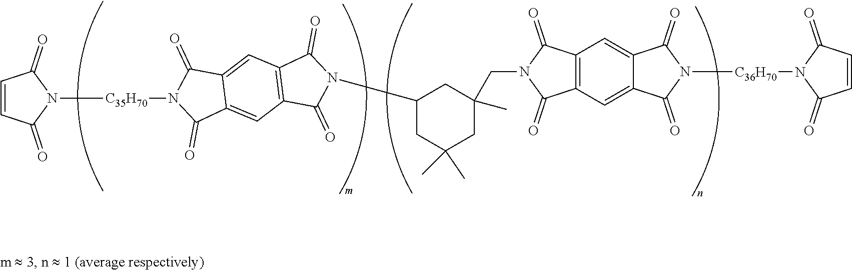

The materials used in this example are as follows.

### [Component (I): Bismaleimide Compound]

I: Bismaleimide compounds shown in Synthesis Examples (1-1) to (1-6) and bismaleimide compounds (BMI-1) to (BMI-3) shown in Comparative Synthesis Examples 1 to 3

[Component (II): Photopolymerization initiator]
II-1: Ethanone, 1-[9-ethyl-6-(2-methylbenzoyl)-9H-carbazol-3-yl]-, 1-(O-acetyloxime) (manufactured by BASF Japan, “IRGACURE OXE-02”)
II-2: 2,4-dimethylthioxanthone (manufactured by Nippon Kayaku Co., Ltd., “DETX-S”)

### Examples 1 to 6 and Comparative Examples 1 to 3

Photosensitive resin compositions of Examples 1 to 6 and Comparative Examples 1 to 3 were prepared by mixing the components (I) and (II) in the amounts (parts by mass) shown in Table 1 and 50 parts by mass of cyclopentanone as a solvent.

TABLE 1

| | | | | | | | | Comparative | | |
|---|---|---|---|---|---|---|---|---|---|---|
| | | Example | | | | | | Example | | |
| Component | Material | 1 | 2 | 3 | 4 | 5 | 6 | 1 | 2 | 3 |
| (I) Bismaleimide | I-1 | 50 | | | | | | | | |
| compound | I-2 | | 50 | | | | | | | |
| | I-3 | | | 50 | | | | | | |
| | I-4 | | | | 50 | | | | | |
| | I-5 | | | | | 50 | | | | |
| | I-6 | | | | | | 50 | | | |
| | Comparative Synthesis Example 1 | | | | | | | 50 | | |
| | Comparative Synthesis Example 2 | | | | | | | | 50 | |
| | Comparative Synthesis Example 3 | | | | | | | | | 50 |
| (II) Photopolymer- | II-1 | 3 | 3 | 3 | 3 | 3 | 3 | 3 | 3 | 3 |
| ization initiator | II-2 | 1 | 1 | 1 | 1 | 1 | 1 | 1 | 1 | 1 |
| Solvent | cyclopentanone | 50 | 50 | 50 | 50 | 50 | 50 | 50 | 50 | 50 |

### <Evaluation of Photosensitive Resin Composition>

The photosensitive resin compositions of Examples 1 to 5 and Comparative Examples 1 to 3 were evaluated as follows. The results are shown in Table 2.

TABLE 2

| | | Example | | | | | | Comparative Example | | |
|---|---|---|---|---|---|---|---|---|---|---|
| Evalutation | | 1 | 2 | 3 | 4 | 5 | 6 | 1 | 2 | 3 |
| Compati- | MIR-3000 | Compatible | Compatible | Compatible | Compatible | Compatible | Compatible | Separated | Separated | Separated |
| bility | | Transparent | Transparent | Transparent | Transparent | Transparent | Transparent | | | |
| | MIR-5000 | Compatible | Compatible | Compatible | Compatible | Compatible | Compatible | Separated | Separated | Separated |
| | | Transparent | Transparent | Transparent | Transparent | Transparent | Transparent | | | |
| Patterning | Sensitivity | 9 | 10 | 9 | 9 | 10 | 10 | 8 | 7 | 8 |
| Performane | (Steps) | | | | | | | | | |
| | Development | A | A | A | A | A | A | A | A | B |
| | Residue | | | | | | | | | |
| Dielectric | Dk | 2.8 | 2.7 | 2.6 | 2.7 | 2.6 | 2.6 | 2.4 | 2.4 | 2.5 |
| properties | Df | 0.0048 | 0.0039 | 0.0033 | 0.0018 | 0.0031 | 0.0020 | 0.0035 | 0.0040 | 0.0030 |
| Heat | Tg (° C.) | 246 | 219 | 214 | 262 | 258 | 229 | 54 | 78 | 145 |
| resistance | Td5 (° C.) | 394 | 392 | 395 | 384 | 382 | 385 | 321 | 316 | 334 |

### (Compatibility)

<Compatibility with MIR-3000>

20 g of each bismaleimide resin composition prepared above, 20 g of the bismaleimide resin represented by formula (21) (MIR-3000, manufactured by Nippon Kayaku Co., Ltd.), and 20 g of cyclopentanone were mixed in a 100 mL transparent glass bottle and heated and mixed at 80° C. for 30 minutes. The mixture was then cooled to room temperature and the appearance was confirmed. The evaluation results are shown in Table 2.

The bismaleimide resin compositions of Examples 1 to 6 were compatible with MIR-3000 and were in a homogeneous state with transparency even after cooling.

In contrast, the bismaleimide resin compositions of Comparative Examples 1 to 3 were separated from MIR-3000.

<Compatibility with MIR-5000>

20 g of each bismaleimide resin composition prepared above, 20 g of the bismaleimide resin represented by formula (22) (MIR-5000, manufactured by Nippon Kavaku Co., Ltd.), and 20 g of cyclopentanone were mixed in a 100 mL transparent glass bottle and heated and mixed at 80° C. for 30 minutes. The mixture was then cooled to room temperature, and the appearance was confirmed. The evaluation results are shown in Table 2.

The bismaleimide resin compositions of Examples 1 to 6 were compatible with MIR-5000, and were in a homogeneous state with transparency even after cooling.

In contrast, the bismaleimide resin compositions of Comparative Examples 1 to 3 separated from MIR-5000.

### (Photosensitivity, Development Residue Evaluation)

The photosensitive resin compositions obtained in Examples 1 to 6 and Comparative Examples 1 to 3 were spin-coated on a silicon substrate and heated at 100° C. for 2 minutes to form a coating film with a thickness of 10 to 15 μm. Next, using an “ultra-high pressure mercury lamp 500 W multilight” manufactured by USHIO, reduction projection exposure was performed with i-ray (365 nm) through a Kodak step tablet No. 2 step tablet. The exposure dose was 2000 mJ/cm². After exposure, the film was heated at 150° C. for 15 minutes and developed using cyclopentanone.

The sensitivity was determined based on the number of the density steps from the highest transmittance of a step tablet manufactured by Kodak (No. 2 step tablet), the number corresponding to the part remained after development of the coating film exposed to light transmitted through the step tablet. The unit is step. The greater the number of steps (values) of the step tablet, the lower the transmittance, and the more the exposed portion exposed to light that has passed through the greater number of steps (values) of the density portion remains during development, the higher the sensitivity is judged to be.

Furthermore, when the developed pattern was observed under a microscope, the pattern with residues in the entire or part of the pattern opening was rated B (bad) in the item of development residues. Those without residues were rated A (good). The resist pattern was then heat-treated in nitrogen at a temperature of 250° C. for 60 minutes and thermally cured. The evaluation results of sensitivity and developability are shown in Table 2.

### (Evaluation of Dialectic Properties (Relative Dielectric Constant: Dk, Dielectric Loss Tangent: Df))

For the evaluation of dielectric properties, the varnish was coated and dried on copper foil with a tabletop coater so that the thickness after drying was 50 μm, and a semi-cured resin film was obtained. Next, the obtained semi-cured resin film was irradiated with UV of 2000 mJ/cm². Thereafter, the resin film was heat-treated in nitrogen at a temperature of to 250° C. for 60 minutes to be thermally cured. Furthermore, the copper foil as the support was removed by physical peeling or etching to obtain a resin film for evaluation. Similarly, a resin film was formed and laminated on the prepared resin film, and the film thickness of the resin film was set to 300 μm.

Then, the resin film was cut into a test piece with a length of 60 mm, a width of 2 mm, and a thickness of 0.3 mm, and the dielectric properties (relative dielectric constant Dk and dielectric loss tangent Df) of the test piece were measured by a cavity resonator perturbation method. The measurement was performed using a vector network analyzer ADMSO10c1 manufactured by AET, and a cavity resonator CP531 (10 GHz band resonator) manufactured by Kanto Electronics Application Development Co., Ltd. The conditions were a frequency of 10 GHz and a measurement temperature of 25° C. The results are shown in Table 2.

### (Evaluation of Glass Transition Temperature (Tg))

For the evaluation of the glass transition temperature, the varnish was coated and dried on copper foil with a tabletop coater so that the thickness after drying was 20 μm, and a semi-cured resin film was obtained. Next, the obtained semi-cured resin film was irradiated with UV of 2000 mi/cm². Thereafter, the resin film was heat-treated in nitrogen at a temperature of 250° C. for 60 minutes to thermally cure the resin film. Furthermore, the copper foil support was removed by physical peeling or etching to obtain a cured resin film for evaluation.

The dynamic viscoelasticity of the cured bismaleimide prepared as above was measured using a dynamic viscoelasticity measuring device (DMA) (manufactured by TA Instruments, RSA-G2) (frequency 1 Hz, tensile mode, heating rate 3° C./min), and the glass transition temperature Tg (° C.) was obtained from the maximum value of the loss tangent (tan δ). The results are shown in Table 2.

### (5% Weight Loss Temperature (Td5) Evaluation)

For the evaluation of the weight loss temperature, the varnish was coated and dried on copper foil with a tabletop coater so that the thickness after drying was 20 μm, and a resin film (semi-cured) was obtained. Next, the obtained resin film (semi-cured) was irradiated with UV of 2000 mJ/cm². Thereafter, the resin film was heat-treated (thermosetting) in nitrogen at a temperature of 250° C. for 60 minutes. Furthermore, the copper foil as the support was removed by physical peeling or etching to obtain a resin film (cured product) for evaluation.

The change in weight of the cured product of the bismaleimide prepared as described above was measured in nitrogen at a temperature rise of 10° C./min using a differential thermal thermogravimeter (TG/DTA6200 manufactured by Seiko Instruments Inc.), and the temperature Td5 (° C.) at which the weight decreased by 5% from the start of the measurement was obtained. The results are shown in Table 2.

As is clear from the results shown in Table 1, the bismaleimide compound obtained using the photosensitive resin composition of the present invention has good compatibility with other resins, and even at low exposure doses, the photocuring of the maleimide group proceeds sufficiently, resulting in an excellent maleimide compound having low dielectric properties and high heat resistance.

This application claims priority from Japanese patent application No. 2022-071709 filed on Apr. 25, 2022.

### INDUSTRIAL APPLICABILITY

As described above, the present invention can provide a bismaleimide compound that is capable of forming a fine pattern at a relatively low exposure dose (2000 mJ/cm² or less), has good compatibility with other resins, and can have a high Tg.

Therefore, such a bismaleimide compound and photosensitive resin composition of the present invention are very useful as a surface protective film, an interlayer insulating film, an insulating film of a rewiring layer, and the like for semiconductor elements.

1. A bismaleimide compound (I) having a cyclic imide bond, obtained by reacting an aromatic diamine (A) represented by the following formula (1), a tetrabasic acid dianhydride (C), and maleic anhydride: 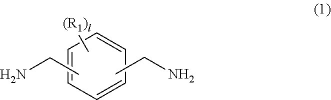
in formula (1),
R₁ independently represents a hydrogen atom, a linear or branched alkyl group having 1 to 6 carbon atoms, a halogen atom, a hydroxy group, or a linear or branched alkoxy group having 1 to 6 carbon atoms, and
1 independently represents an integer of 1 to 4.

2. A bismaleimide compound (I) having a cyclic imide bond, obtained by reacting an aromatic diamine (A) represented by the following formula (1), a tetrabasic acid dianhydride (C), and maleic anhydride, the bismaleimide compound (I) having a cyclic imide bond being obtained by reacting the diamine (A), the tetrabasic acid dianhydride (C), the maleic anhydride, and a divalent organic diamine (B) having 6 to 200 carbon atoms other than the aromatic diamine (A): 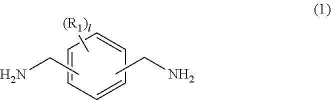
in formula (1),
R₁ independently represents a hydrogen atom, a linear or branched alkyl group having 1 to 6 carbon atoms, a halogen atom, a hydroxy group, or a linear or branched alkoxy group having 1 to 6 carbon atoms, and
each 1 independently represents an integer of 1 to 4.

3. A bismaleimide compound (I) represented by the following general formula (2): 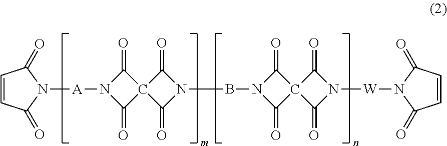
in formula (2),
C independently represents a tetravalent organic group containing a cyclic structure,
B independently represents a divalent hydrocarbon group having 6 to 200 carbon atoms,
W is A or B,
m is 1 to 100, n is 0 to 100, the order of each repeating unit bracketed by m and n is not limited, and the bonding style may be alternate, block, or random, and
A independently represents a divalent linking group represented by the following formula (3): 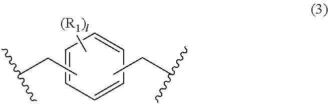
in formula (3),
R₁ independently represents a hydrogen atom, a linear or branched alkyl group having 1 to 6 carbon atoms, a halogen atom, a hydroxy group, or a linear or branched alkoxy group having 1 to 6 carbon atoms, and
1 independently represents an integer of 1 to 4.

4. The bismaleimide compound (I) according to claim 1, wherein the tetrabasic acid dianhydride (C) comprises a compound selected from the group consisting of the following formulas (4) to (12): 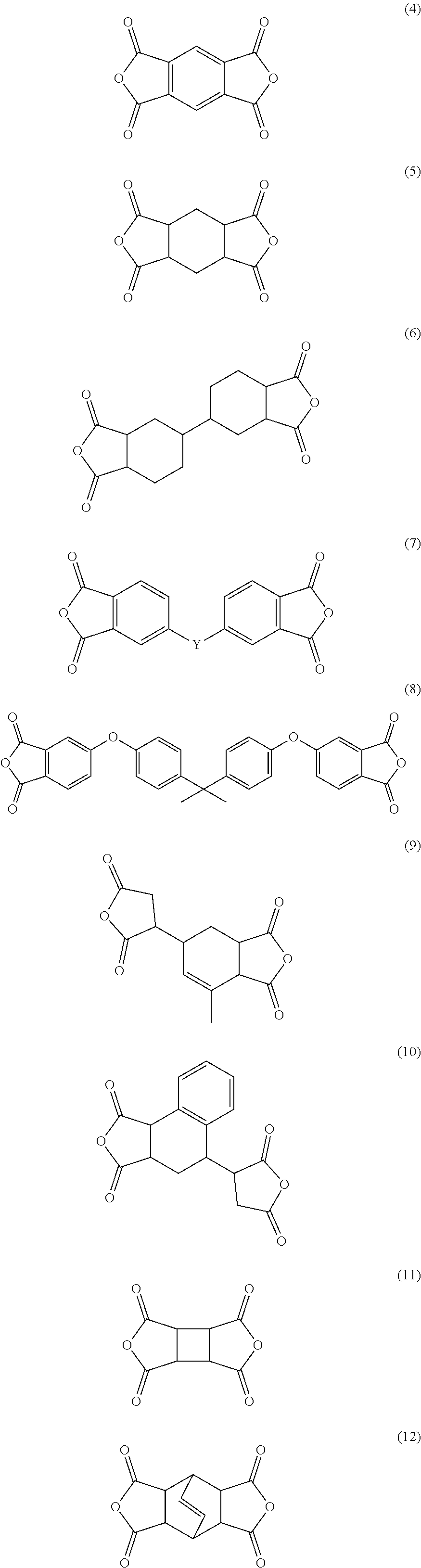
in formula (7),
Y represents C(CF₃)₂, SO₂, CO, an oxygen atom, a direct bond, or a divalent linking group represented by the following formula (13):

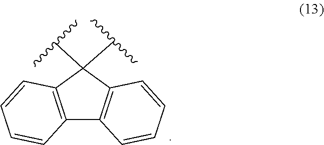 [SMILES: *C1(*)c2ccccc2-c2ccccc21]

5. The bismaleimide compound (I) of claim 3, that is a maleimide compound of an amine compound represented by the following formula (14): 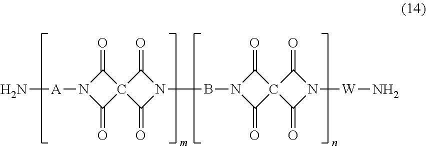
in formula (14),
C independently represents a tetravalent organic group having a cyclic structure,
B independently represents a divalent hydrocarbon group having 6 to 200 carbon atoms,
W is A or B,
m is 1 to 100, n is 0 to 100, the order of the repeating units bracketed by m and n is not limited, and the bonding style may be alternate, block, or random, and
A independently represents a divalent linking group represented by the following formula (3): 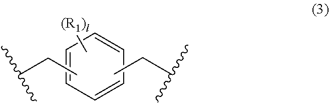
in formula (3),
R₁ independently represents a hydrogen atom, a linear or branched alkyl group having 1 to 6 carbon atoms, a halogen atom, a hydroxy group, or a linear or branched alkoxy group having 1 to 6 carbon atoms, and 1 independently represents
an integer of 1 to 4.

6. The bismaleimide compound (I) according to claim 1, wherein the tetrabasic acid dianhydride (C) is a compound represented by the following formula (15):

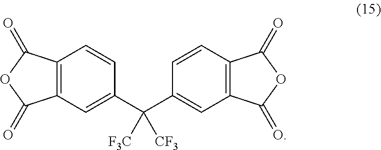 [SMILES: O=C1OC(=O)c2cc(C(c3ccc4c(c3)C(=O)OC4=O)(C(F)(F)F)C(F)(F)F)ccc21]

7. The bismaleimide compound (f) according to claim 1, wherein the tetrabasic acid dianhydride (C) is a compound represented by the following formula (8):

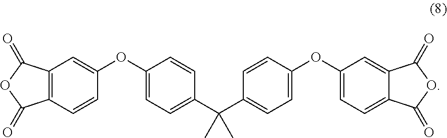 [SMILES: CC(C)(c1ccc(Oc2ccc3c(c2)C(=O)OC3=O)cc1)c1ccc(Oc2ccc3c(c2)C(=O)OC3=O)cc1]

8. The bismaleimide compound (I) according to claim 1, wherein the tetrabasic acid dianhydride (C) is a compound represented by the following formula (5):

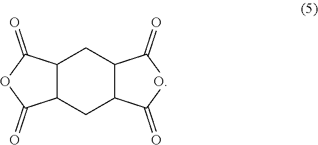 [SMILES: O=C1OC(=O)C2CC3C(=O)OC(=O)C3CC12]

9. The bismaleimide compound (f) according to claim 1, wherein the tetrabasic acid dianhydride (C) is a compound represented by the following formula (9):

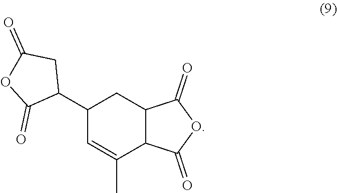 [SMILES: CC1=CC(C2CC(=O)OC2=O)CC2C(=O)OC(=O)C12]

10. The bismaleimide compound (I) according to claim 1, wherein the tetrabasic acid dianhydride (C) is a compound represented by the following formula (10):

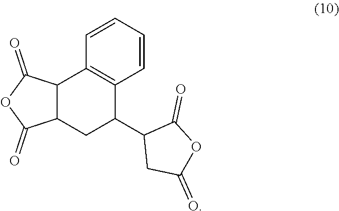 [SMILES: O=C1CC(C2CC3C(=O)OC(=O)C3c3ccccc32)C(=O)O1]

11. A resin composition comprising
the bismaleimide compound (I) according to claim 1, and
a compound capable of reacting with a maleimide group.

12. The resin composition according to claim 11, wherein the compound capable of reacting with the maleimide group is at least one selected from the group consisting of: maleimide compounds other than the bismaleimide compound (I), cyanate ester compounds, phenolic resins, epoxy resins, oxetane resins, benzoxazine compounds, carbodiimide compounds, and compounds having an ethylenically unsaturated group.

13. A resin composition comprising the bismaleimide compound (I) according to claim 1, and a photopolymerization initiator or a curing catalyst.

14. The resin composition according to claim 11, further comprising a filler.

15. A cured object of a resin composition comprising the bismaleimide compound (I) according to claim 1.

16. A semiconductor element comprising:
a surface protection film,
an interlayer insulating film, or
an insulating film of a redistribution layer,
which contains the bismaleimide compound (I) according to claim 1.

17. A dry film resist comprising a composition comprising
the bismaleimide compound (I) according to claim 1, and
a photopolymerization initiator.
